(19) United States
(12) Patent Application Publication
(10) Pub. No.: US 2026/0173971 A1
(43) Pub. Date: Jun. 18, 2026

(54) BONDED SEMICONDUCTOR GROUPS IN STACKED MEMORY ARCHITECTURES

(71) Applicant: Micron Technology, Inc., Boise, ID (US)

(72) Inventors: Bharat Bhushan, Boise, ID (US); Kunal R. Parekh, Boise, ID (US); Akshay N. Singh, Boise, ID (US)

(21) Appl. No.: 19/412,619

(22) Filed: Dec. 8, 2025

Related U.S. Application Data
(60) Provisional application No. 63/733,938, filed on Dec. 13, 2024.

(51) Int. Cl. H10W 90/28; H10W 72/90; H10W 80/00; H10W 90/00

(52) U.S. Cl. CPC H10W 90/28; H10W 72/952; H10W 80/312; H10W 90/792

(57) ABSTRACT

Methods, systems, and devices for bonded semiconductor groups in stacked memory architectures are described. A first semiconductor component may include first circuitry, first contacts formed of a first conductive material, and second contacts formed of a second conductive material. A second semiconductor component may include second circuitry, third contacts, and fourth contacts formed of the first conductive material. The second semiconductor component may be bonded with the first semiconductor component based on the first contacts and the third contacts. A third semiconductor component may include third circuitry, fifth contacts formed of the first conductive material, and sixth contacts formed of a third conductive material. The third semiconductor component may be bonded with the second semiconductor component based on the fifth contacts and the fourth contacts. The second contacts and the sixth contacts may support connections of the first, second, and third semiconductor components with other components.

### CROSS REFERENCE

The present Application for Patent claims priority to U.S. patent application Ser. No. 63/733,938 by Bhushan et al., entitled “BONDED SEMICONDUCTOR GROUPS IN STACKED MEMORY ARCHITECTURES,” filed Dec. 13, 2024, which is assigned to the assignee hereof, and which is expressly incorporated by reference in its entirety herein.

### TECHNICAL FIELD

The following relates to one or more semiconductor systems, including bonded semiconductor groups in stacked memory architectures.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports bonded semiconductor groups in stacked memory architectures in accordance with examples as disclosed herein.

FIG. 2 shows an example of a system that supports bonded semiconductor groups in stacked memory architectures in accordance with examples as disclosed herein.

FIG. 3 shows an example of a semiconductor system that supports bonded semiconductor groups in stacked memory architectures in accordance with examples as disclosed herein.

FIG. 4A through 4F illustrate examples of operations that support bonded semiconductor groups in stacked memory architectures in accordance with examples as disclosed herein.

FIG. 5A through 5E illustrate examples of operations that support bonded semiconductor groups in stacked memory architectures in accordance with examples as disclosed herein.

FIG. 6 shows an example of a semiconductor system that supports bonded semiconductor groups in stacked memory architectures in accordance with examples as disclosed herein.

FIG. 7 shows an example of a semiconductor system that supports bonded semiconductor groups in stacked memory architectures in accordance with examples as disclosed herein.

FIGS. 8 and 9 show flowcharts illustrating a method or methods that support bonded semiconductor groups in stacked memory architectures in accordance with examples as disclosed herein.

### DETAILED DESCRIPTION

Some semiconductor systems (e.g., memory systems, processor systems, systems having a combination of memory and processing) may include a stack of semiconductor components (e.g., semiconductor dies), which may include one or more memory dies (e.g., dynamic random access memory (DRAM) dies, memory dies, array dies, memory array dies) or one or more stacks of memory dies that are stacked with a logic die that is operable to access a set of memory arrays distributed across the one or more memory dies. Such a stacked architecture may be implemented as part of a high bandwidth memory (HBM) system or a coupled dynamic random access memory (DRAM) system (e.g., a closely-coupled DRAM system, a 3D stacked memory system), among other examples, and may support solutions for memory-centric logic, such as graphics processing units (GPUs), among other implementations. In some examples, an HBM system may include one or more memory dies coupled (e.g., bonded, stacked) with a logic die. In some examples, a coupled DRAM system may be closely coupled (e.g., physically coupled, electrically coupled, directly coupled) with a processor, such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

In some stacked semiconductor systems, a quantity of semiconductor dies (e.g., DRAM dies, logic dies, host dies) included in a stack may increase, such as to support increasing storage capacity or storage density. However, stacked semiconductor systems may be subject to a height dimension constraint (e.g., a threshold thickness), which may affect (e.g., constrain, limit) a quantity of dies in a stack. Some die stacking techniques may not support an increasing a quantity of stacked dies while satisfying such constraints. For example, some stacked systems may include dies that are bonded together using respective solder connections (e.g., micro-bumps (μ-bumps), solder balls, solder contacts), which may be a relatively large contribution to an overall height dimension of the stack.

In accordance with one or more aspects described herein, a semiconductor system (e.g., a semiconductor device, an HBM device, a coupled DRAM device, a stacked processing device, or other stacked system) may be fabricated to support various bonding operations (e.g., fusion bonding, hybrid bonding) that group multiple semiconductor component together (e.g., as a group of two, as a group of three or more, forming a two-high die stack, forming a three-high die stack) prior to being coupled with other semiconductor components (e.g., via solder-based connections, via fusion bonding, via hybrid bonding). For example, two or more semiconductor components (e.g., dies, wafers) may be bonded together (e.g., as a sub-stack, as a stack portion, by fusion bonding), and a set of contacts (e.g., solder bumps) that support connections with other semiconductor components (e.g., other stacks, a logic component) may be formed over a first of the bonded semiconductor components. Each of the stacked semiconductor components may include contacts, vias, interconnection circuitry, and other elements (e.g., circuit elements, including various conductive materials) that support the bonding operations and access to internal circuitry (e.g., memory array circuitry, logic circuitry, processing circuitry, bypass circuitry) of the respective semiconductor component. Accordingly, a stacked semiconductor system may include relatively fewer sets of solder connections between respective semiconductor dies (e.g., using thinner fusion bonding techniques), which may reduce the overall thickness of a stacked system. By reducing the thickness dimension, stacked semiconductor systems may be configured to support a relatively greater quantity of dies in a stack, thereby supporting increased storage capacity and storage density. Additionally, the various techniques described herein may support enhanced device performance, improved manufacture yield, and other benefits for semiconductor systems.

In addition to applicability in memory systems as described herein, techniques for bonded semiconductor groups in stacked memory architectures may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by enabling increased storage capacity, increased storage density, or both, which may improve support for data intensive applications (e.g., AI implementations), among other benefits.

Features of the disclosure are illustrated and described in the context of systems and architectures. Features of the disclosure are further illustrated and described in the context of devices and flowcharts.

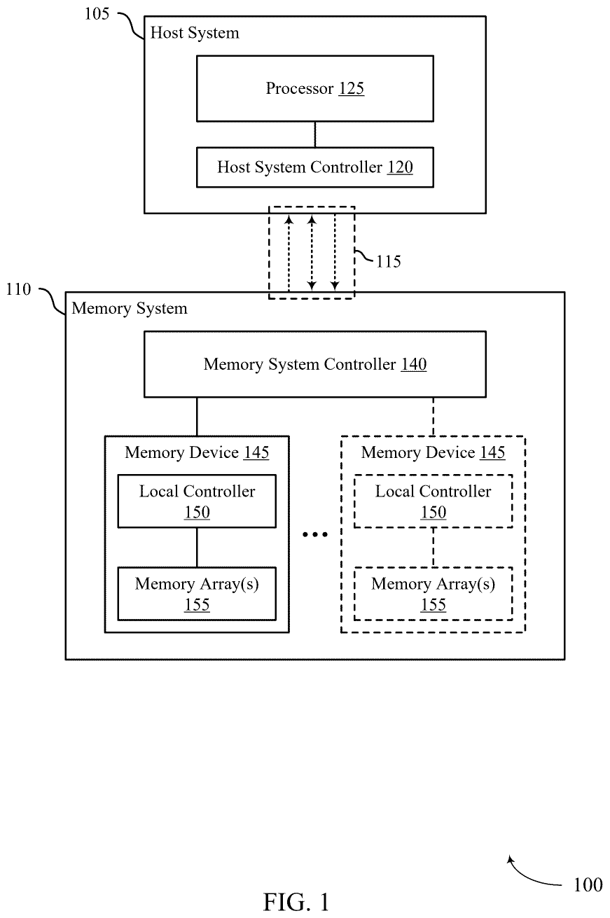

FIG. 1 shows an example of a system 100 that supports bonded semiconductor groups in stacked memory architectures in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or a combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, portions of a memory die) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of the system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies (e.g., one or more memory stacks). In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks. In some examples, multiple semiconductor dies of a memory system 110 or of a system 100 (e.g., an HBM system including aspects of a memory system 110, a coupled DRAM system including aspects of a memory system 110 and a host system 105) may include one or more array dies stacked with a logic die (e.g., that includes aspects of the host system 105, that is coupled with another die that includes the host system 105) that includes interface blocks operable to access a set of memory arrays 155 distributed across the one or more second dies.

Some systems 100 may support a stacked architecture, which may be subject to a height dimension constraint. However, some stacking techniques may be insufficient to support increasing a quantity of semiconductor dies (e.g., a die that includes a memory system 110 or a subcomponent thereof, a die that includes a host system 105 or a subcomponent thereof) in the stack while satisfying the height constraints. In accordance with one or more aspects described herein, a system 100, or portion thereof (e.g., a memory system 110, a memory device 145) may be fabricated based on bonding (e.g., fusion bonding, hybrid bonding) multiple semiconductor components together before coupling with other semiconductor components in a stack. For example, two or more semiconductor components may be bonded together (e.g., by fusion bonding), and a set of solder bumps may be formed over a first of the bonded semiconductor components. Each of the stacked semiconductor components may include interconnection circuitry (e.g., back-end-of-line (BEOL) circuitry, through silicon vias (TSVs), aluminum contacts) such that the set of solder bumps are electrically connected with internal circuitry of each of the stacked semiconductor components (e.g., associated with one or more memory arrays 155, a memory system controller 140, a local controller 150, a processor 125, a host system controller 120, or a combination thereof). Accordingly, the system 100, or portion thereof (e.g., in a stacked architecture), may include relatively fewer solder connections between respective semiconductor components, which may reduce the overall height dimension of the system 100 and support increased storage capacity, increased storage density, or both.

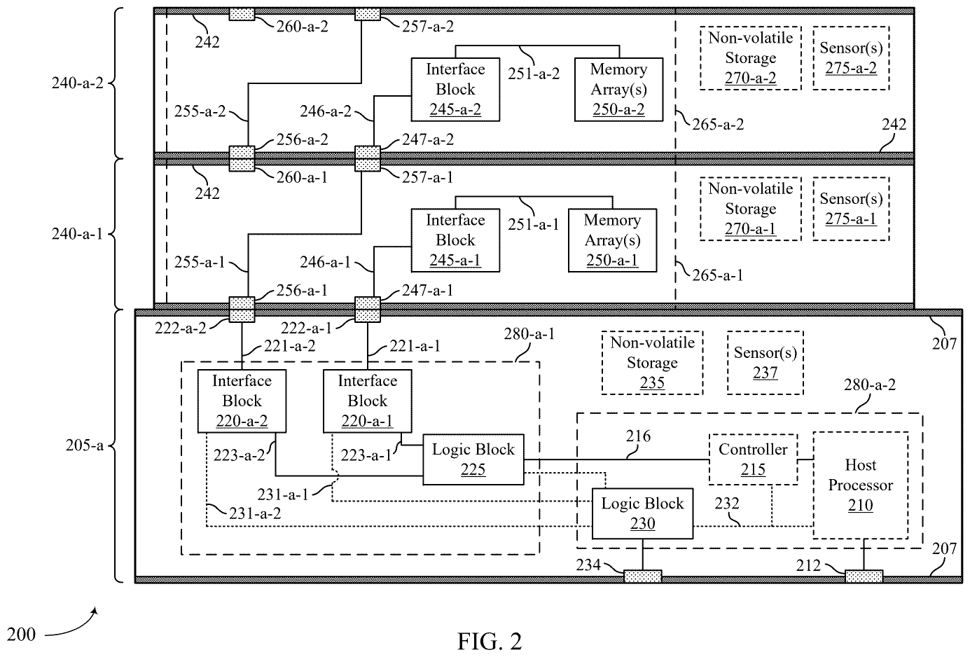

FIG. 2 shows an example of a system 200 (e.g., a semiconductor system, a system of coupled semiconductor dies, an HBM system, a coupled DRAM system) that supports bonded semiconductor groups in stacked memory architectures in accordance with examples as disclosed herein. The system 200 illustrates an example of a die 205 (e.g., a die 205-a, a semiconductor die, a logic die, a processor die, a host die, a logic unit) that is coupled with one or more dies 240 (e.g., dies 240-a-1 and 240-a-2, semiconductor dies, memory dies, array dies, memory units, of a memory stack). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 (e.g., 8, 12, 16, 24, or more dies 240) coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations (e.g., coupled DRAM implementations), a die 205 may include a host processor 210. A host processor 210 may be an example of a host system 105, or a portion thereof (e.g., a processor 125, aspects of a host system controller 120, or both). A host processor 210 may include one or more processor cores that are configured to perform operations that implement storage of the memory arrays 250 (e.g., to support an application or other function of a host system 105, which may request access to the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. For example, a host interface 216 may be configured in accordance with an industry standard, which may define channels, commands, clocking, and deterministic responses and timing, among other characteristics of the host interface 216. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling, clock signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220, in a coupled DRAM implementation, in accordance with a command and address protocol) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216, in an HBM implementation), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory arrays 250 (e.g., for parallel or otherwise coordinated access of the multiple memory arrays 250). For example, such a channel set may be associated with multiple memory arrays 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth configuration of the system 200, in accordance with a closely-coupled configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220 (e.g., in accordance with a command and address protocol). The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 or one or more controllers 215 (e.g., via a bus 232, via a contact 212 for a host processor 210 or controller 215 external to a die 205), such that the logic block 230 may support an interface between the host processor 210 or one or more controllers 215 and the logic blocks 225 or interface blocks 220. For example, a host processor 210 or a controller 215 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210 or controller 215. Additionally, or alternatively, a logic block 230 may communicate with a host processor 210 or a controller 215, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

In some examples, respective signals may be routed between a die 205 die and one or more dies 240. For example, each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240). In some implementations, at least a portion of a bus 221, a bus 246, or a bus 255, or any combination thereof may include one or more conductors in a redistribution layer (RDL) of a respective die (e.g., above or below a semiconductor substrate of the die). Additionally, or alternatively, in some implementations, at least a portion of a bus 221, a bus 246, or a bus 255, or any combination thereof may include one or more vias that are formed through a semiconductor substrate of a respective die (e.g., as one or more through-silicon vias (TSVs)).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205-a with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube,” a memory stack, or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

Some systems 200 may be subject to a height dimension constraint, and some stacking techniques may be insufficient to support increasing a quantity of semiconductor dies (e.g., dies 205, dies 240, or both) in the stack while satisfying the height constraint. In accordance with one or more aspects described herein, a system 200 may be fabricated based on bonding (e.g., fusion bonding, hybrid bonding) multiple semiconductor dies (e.g., two dies 240, three dies 240, more than three dies 240) together before adding them to other semiconductor dies of the system 200. For example, two or more dies 240 may be bonded together (e.g., in the form of semiconductor dies, in the form of one or more semiconductor wafers that include respective dies) prior to bonding with other dies (e.g., with another group of dies 240, with a die 205), and a set of solder bumps may be formed over a first of the bonded dies (e.g., formed over one or more of the contacts 247, contacts 256, contacts 257, contacts 260, contacts 222, contact 234, one or more contacts 212). Each of the dies (e.g., of the intermediate stack) may include interconnection circuitry (e.g., BEOL circuitry, TSVs, internal contacts) such that the set of solder bumps are electrically connected with internal circuitry of each of the dies (e.g., associated with one or more memory arrays 250, interface blocks 245, non-volatile storage 270, sensors 275, interface blocks 220, logic blocks 225, or a combination thereof). Accordingly, a system 200 (e.g., in a stacked architecture) may include relatively fewer sets of solder connections between respective dies, which may reduce the overall height dimension of the system 200 and support increased storage capacity, increased storage density, or both.

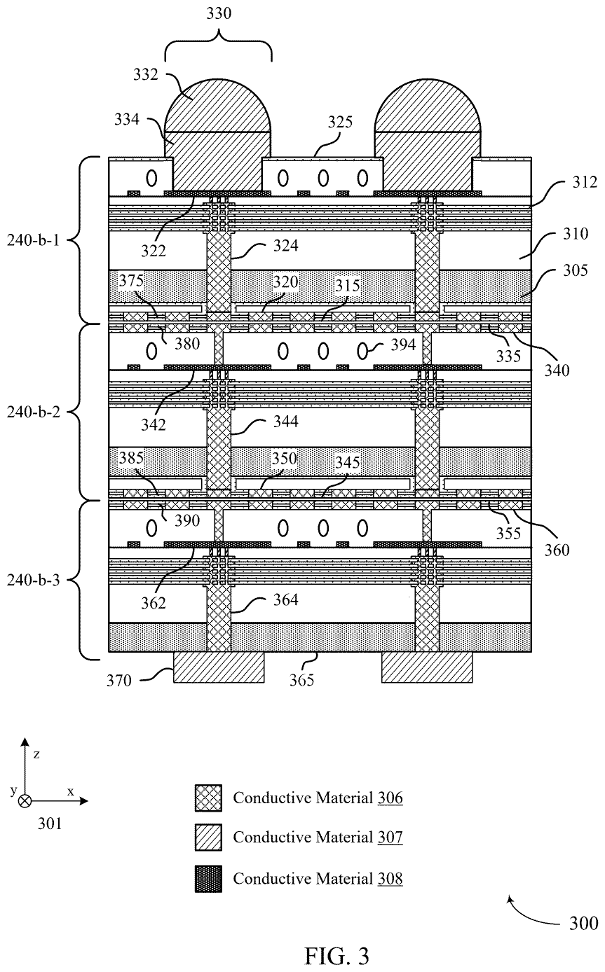

FIG. 3 shows an example of a semiconductor system 300 that supports bonded semiconductor groups in stacked memory architectures in accordance with examples as disclosed herein. The semiconductor system 300 may be an example of or include one or more aspects of a system 100 or a system 200, and may be described with reference to an x-direction, a y-direction, and a z-direction of a coordinate system 301. The semiconductor system 300 may include a stack of components including dies 240-b-1 through 240-b-3 (e.g., core dies, DRAM dies, semiconductor components). Each die 240-b may include a respective substrate 305 (e.g., one or more substrate materials, a silicon substrate, a portion of crystalline semiconductor) and one or more dielectric materials 310 (e.g., oxide, nitride, carbide). Each die 240-b may also include respective circuitry (not shown), which may be one or more memory arrays 155, memory arrays 250, interface blocks 245, or other circuitry. For example, the die 240-b-1 may include first circuitry, the die 240-b-2 may include second circuitry, and the die 240-b-3 may include third circuitry. In some examples, each instance of circuitry may be included within a portion of a dielectric material 310 and may be at least partially embedded in (e.g., formed at least in part using) the respective substrates 305. Although the techniques are described in the context of dies 240, the techniques may also be applied with other semiconductor components, such as one or more dies 205, or a combination of one or more dies 240 and one or more dies 205, among others.

The dies 240-b may include features formed using various conductive materials including the conductive material 306, the conductive material 307, and the conductive material 308, each of which may be or include copper, aluminum, tungsten, titanium, solder, other metallic conductive material, or a combination thereof (e.g., as a combination of multiple materials, as an alloy, as separate portions of different materials). For example, the conductive material 306 may be or include copper, the conductive material 307 may be or include nickel, aluminum, solder, or a combination thereof, and the conductive material 308 may be or include aluminum, and such different materials may support aspects of differential processing, different bonding techniques, or a combination thereof. The dielectric materials of the dies 240-b may be or include silicon carbide, silicon oxide, silicon nitride, silicon carbon nitride, tetraethyl orthosilicate (TEOS), or a combination thereof. For example, the dielectric materials 310 may include silicon oxide and other dielectric materials of the dies 240-b (e.g., dielectric materials 312) may include silicon carbon nitride.

The die 240-b-1 may have a side 315 (e.g., a back side, a surface) that is associated with (e.g., include, intersect with, be coincident with) a set of contacts 320 (e.g., hybrid bond pads), which may be formed of a conductive material 306 (e.g., copper). The die 240-b-1 may also have a side 325 (e.g., a front side, a surface, opposite the side 315) that is associated with a set of contacts 330 (e.g., solder bumps, μ-bumps, conductive pillars, copper pillars), and the side 325 also may be considered as a side of the semiconductor system 300. The contacts 330 may be formed of a conductive material 307 (e.g., nickel, solder, copper), which may be different than the conductive material 306. For example, the contacts 330 may include portions 332 (e.g., a first subset of contacts) that are configured to support a coupling between the semiconductor system 300 and one or more other semiconductor components (not shown). The contacts 330 may also include portions 334 (e.g., a second subset of contacts) that are configured to support a coupling between the circuitry of the die 240-b-1 and the portions 332. In some examples, the portions 332 and the portions 334 may be formed of respective conductive materials 307 that are different from one another (e.g., the portions 332 may be solder and the portions 334 may be nickel).

The die 240-b-2 may have a side 335 (e.g., a front side) that is associated with a set of contacts 340 (e.g., hybrid bond pads), which may be formed of the conductive material 306. The die 240-b-2 may also have a side 345 (e.g., a back side, opposite the side 335) that is associated with a set of contacts 350 (e.g., hybrid bond pads), which may be formed of the conductive material 306. In some examples, the side 335 of the die 240-b-2 may be bonded with the side 315 of the die 240-b-1 based on a fusion of contacts 340 with contacts 320 (e.g., in accordance with a front-to-back (F2B) bonding arrangement).

The die 240-b-3 may have a side 355 (e.g., a front side) that is associated with a set of contacts 360 (e.g., hybrid bond pads), which may be formed of the conductive material 306. The die 240-b-3 may also have a side 365 (e.g., a back side, opposite the side 355) that is associated with a set of contacts 370 (e.g., under bump metallization (UBM) pads, nickel pads, backside bumps). In some examples, the side 365 also may be considered as a side of the semiconductor system 300. For example, the semiconductor system 300 may have the contacts 330 on a first side (e.g., the side 325) of the semiconductor system 300 and may have the vias 364, contacts 370, or both on a second side (e.g., the side 365) of the semiconductor system 300. In some other examples (not shown), a semiconductor system 300 may be formed with contacts 330 on the side 365 (e.g., as backside bumps) and vias 364, contacts 370, or both on the side 325 (e.g., as frontside pillars). The contacts 370 may be formed of the conductive material 307, which may be different than the conductive material 306. In some examples, the side 355 of the die 240-b-3 may be bonded with the side 345 of the die 240-b-2 based on a fusion of contacts 360 with contacts 350 (e.g., in accordance with an F2B bonding arrangement). Accordingly, the system 300 may illustrate an example of a three-high (3H) F2B semiconductor system which, in some examples, may be bonded with another semiconductor component, such as a semiconductor component associated with one or more controllers, or another system 300 (e.g., in a 2-high stack of systems 300, in a 4-high stack of systems 300, in a 8-high stack of systems 300, among other examples), or a combination thereof.

In some examples, a bond between dies 240-b (e.g., in a system 300) may be associated with a hybrid bonding in which both conductive materials and dielectric materials of the surfaces (e.g., bonding surfaces) each die 240-b are respectively fused together. For example, the side 315 of the die 240-b-1 may be bonded with the side 335 of the die 240-b-2 based on hybrid bonding that may also include a fusion of a dielectric material 375 of the die 240-b-1 with a dielectric material 380 of the die 240-b-2. Additionally, the side 345 of the die 240-b-2 may be bonded with the side 355 of the die 240-b-3 based on hybrid bonding that may also include a fusion of a dielectric material 385 of the die 240-b-2 with a dielectric material 390 of the die 240-b-3.

The die 240-b-1 may also include a set of contacts 322 (e.g., aluminum pads, embedded contacts, intermediate contacts), which may be formed of a conductive material 308 that is different than the conductive material 306, or the conductive material 307, or both. In some examples, one or more of the contacts 322 may facilitate a coupling between the circuitry of the die 240-b-1 and the contacts 330. The die 240-b-2 may also include a set of contacts 342 (e.g., aluminum pads, embedded contacts, intermediate contacts) that are formed of the conductive material 308. In some examples, one or more of the contacts 340 may be coupled with circuitry of the die 240-b-2 based on (e.g., via) the contacts 342. The die 240-b-3 may also include a set of contacts 362 (e.g., aluminum pads, embedded contacts, intermediate contacts) that are formed of the conductive material 308. In some examples, the contacts 360 may be coupled with the circuitry of the die 240-b-3 based on the contacts 362.

In some examples, dies 240-b may include various vias that support an interconnection of circuitry across the dies 240-b. For example, a semiconductor system 300 may include one or more vias 324 (e.g., through silicon vias (TSVs), formed of copper) through a substrate 305 of the die 240-b-1, and vias 324 may be coupled one or more of the contacts 320, with one or more of the contacts 330 (e.g., by way of BEOL circuitry and the contacts 322), or both. A semiconductor system 300 may also include one or more vias 344 (e.g., TSVs formed of copper) through a substrate 305 of the die 240-b-2, and vias 344 may be coupled with one or more of the contacts 340 (e.g., by way of BEOL circuitry and the contacts 322), one or more of the contacts 350, or both. The semiconductor system 300 may also include one or more vias 364 (e.g., TSVs formed of copper) through a substrate 305 of the die 240-b-3, and vias 364 may be coupled with one or more the contacts 360 (e.g., by way of BEOL circuitry and the contacts 322), with one or more of the contacts 370 (e.g., in accordance with a conductive pillar), or both.

In some examples, circuitry of the die 240-b-1, circuitry the die 240-b-2, and circuitry of the die 240-b-3 may include respective portions of memory array circuitry associated with a semiconductor system 300. In some examples, a semiconductor system 300 may be separated (e.g., diced, singulated) from one or more wafers (e.g., the dies 240-b may be bonded together based on a wafer-to-wafer (W2W) hybrid bond) that includes multiple semiconductor systems 300. In some other examples, the dies 240-b may be bonded after singulation (e.g., in accordance with die-to-die (D2D) bonding techniques). In some examples, dies 240-b may include one or more airgaps 394 (e.g., AI airgaps, in dielectric materials 310), which may support improved electrical characteristics and performance of the dies 240-b. Dies 240-b of a semiconductor system 300 may be associated with respective height dimensions (e.g., thickness, along the z-direction), which may be different from each other. For example, the die 240-b-1 and the die 240-b-3 may be associated with a first height and the die 240-b-2 may be associated with a second height that is different than (e.g., greater than, less than) the first height, among other examples.

By including a set of multiple dies 240-b in a bonded stack (e.g., in accordance with a hybrid bonding or a fusion bonding), a semiconductor system 300 may support a reduced thickness (e.g., along the z-direction, compared with solder bonding). For example, a bonded stack of dies 240-b may support a reduced quantity of contacts 330 included a system (e.g., a system 100, a memory system 110, a memory device 145, a system 200), thus supporting a greater quantity of dies 240-b that may be included in the system while satisfying a height constraint. Accordingly, by incorporating one or more aspects of a semiconductor system 300, systems may support increased storage capacity, increased storage density, and improved performance, among other benefits.

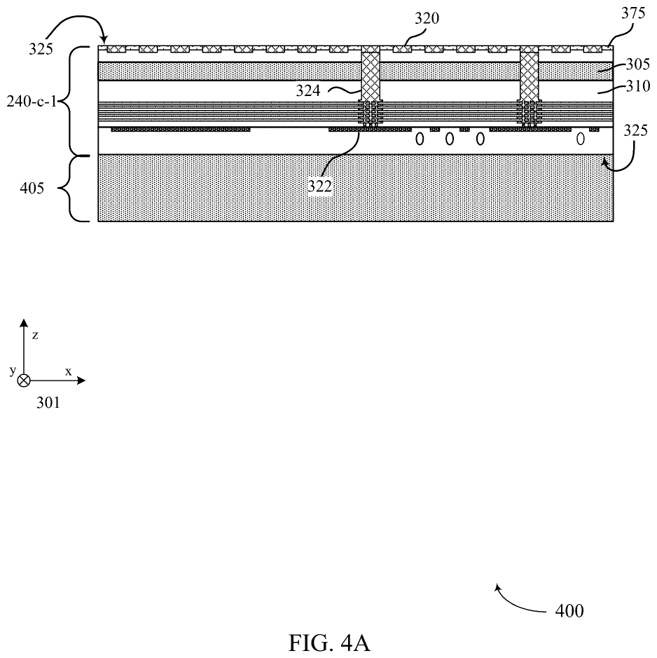

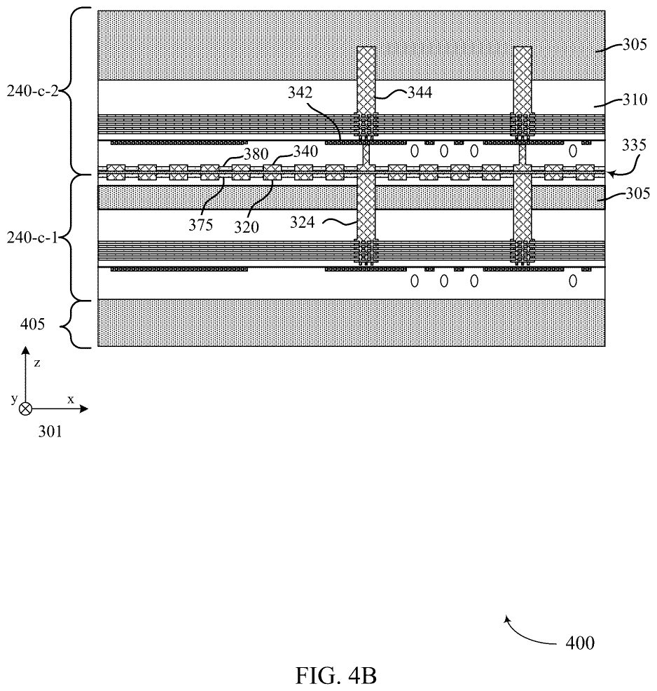

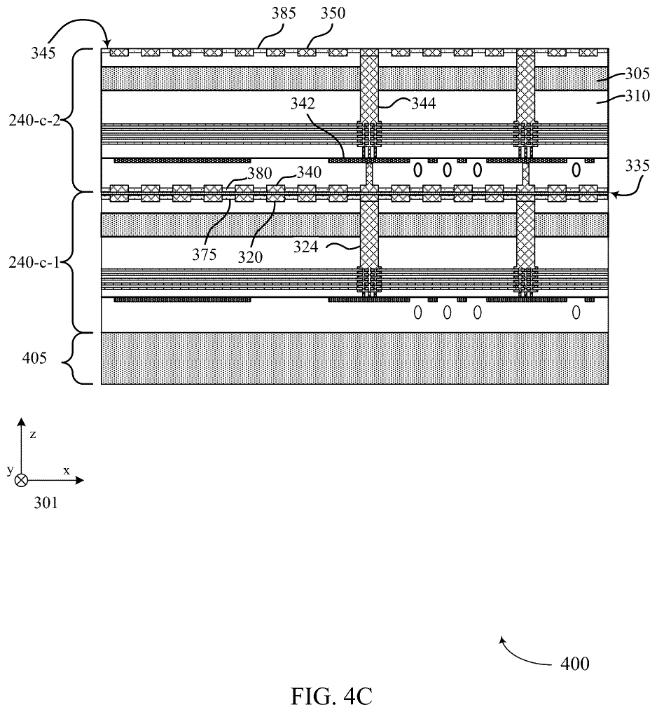

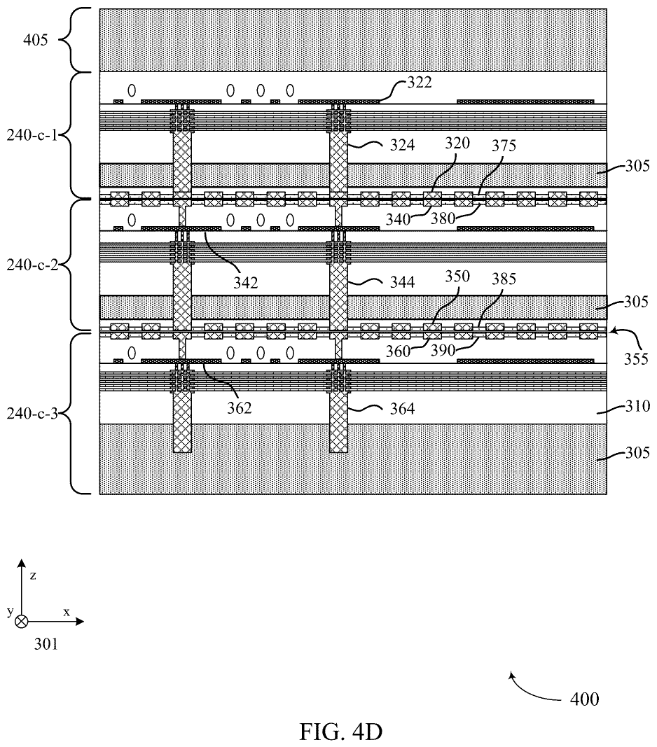

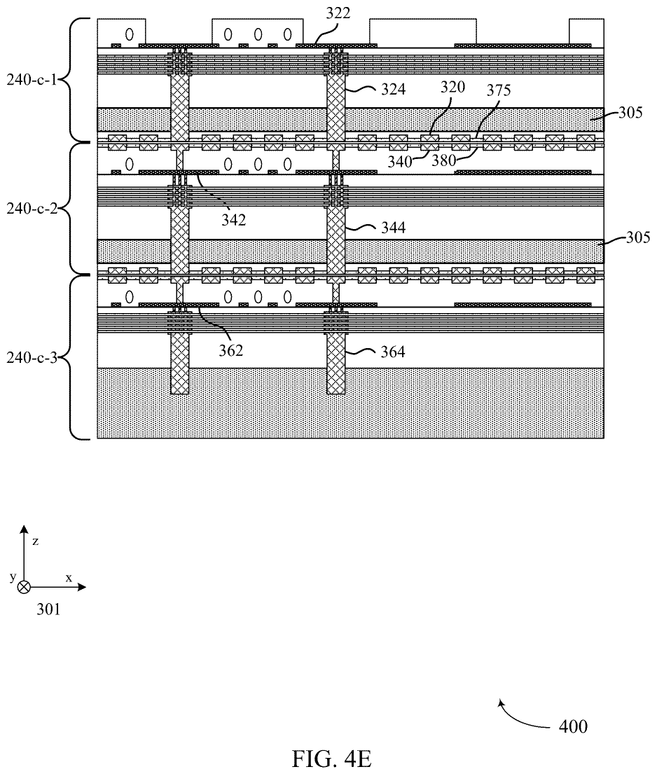

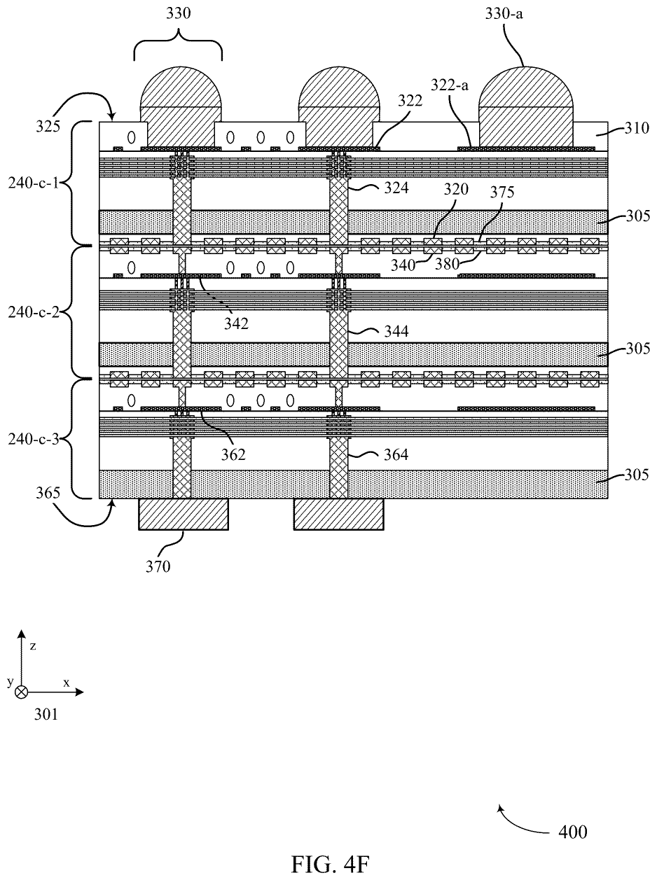

FIGS. 4A through 4F illustrate examples of operations that support bonded semiconductor groups in stacked memory architectures in accordance with examples as disclosed herein. Operations are illustrated with reference to a system 400 (e.g., a semiconductor system, a semiconductor stack, a semiconductor device, a semiconductor subcomponent), which may be an example of or include an electronic device (e.g., a semiconductor system 300, a system 100, a memory system 110, a host system 105, a system 200), or portion thereof. For example, FIGS. 4A through 4F may illustrate aspects of a first sequence of operations that support manufacturing a system 100 or a portion thereof, a system 200 or a portion thereof, a semiconductor system 300 or a portion thereof, or some other device. Each of the figures may be described with reference to an x-direction, a y-direction, and a z-direction of a coordinate system 301. Operations illustrated in and described with reference to FIGS. 4A through 4F may be performed by a manufacturing system, such as a semiconductor fabrication system configured to perform additive operations (e.g., deposition, epitaxy, bonding), subtractive operations (e.g., etching, trenching, planarizing, polishing, grinding, scraping), modifying operations (e.g., oxidizing, doping, reacting, converting), and supporting operations (e.g., masking, patterning, photolithography, aligning), among other operations that support the described techniques.

In some examples, portions of the system 400 that are illustrated with a same fill pattern may be formed of same or similar materials and portions that are illustrated with different patterns may be formed of different materials. Various dielectric materials are described herein, which may include an aluminum nitride, a silicon carbide, a silicon oxide, a silicon nitride, a silicon carbon nitride, a tetraethyl orthosilicate (TEOS), a boron arsenide, some other dielectric material, or any combination thereof. Additionally, conductive materials described herein may include copper, aluminum, tungsten, titanium, some other conductive material, or any combination thereof.

FIG. 4A shows an example of a cross-sectional view of the system 400 after a first set of one or more fabrication operations. For example, the first operations may include forming or providing a semiconductor component (e.g., a wafer) that includes one or more dies 240-c-1 (e.g., a first semiconductor component) that include first circuitry (not shown) of the system 400, such as one or more memory arrays 155, memory arrays 250, interface blocks 245, local controller 150. In the first operations, one or more dies 240-c-1 may be singulated from a semiconductor wafer, or may be included in a semiconductor wafer (e.g., before singulation). In some examples, the semiconductor component (e.g., wafer) that includes the one or more dies 240-c-1 may include a substrate 305, a dielectric material 310, and one or more vias 324, and forming the die 240-c-1 may include forming one or more vias 324 through a substrate 305 of the die 240-c-1. In some examples, the vias 324 may be formed in accordance with a “via-middle” process in which the one or more vias 324 are formed prior to the formation of one or more other components of the die 240-c-1, or bonding with other die(s) 240-c. In some other examples, vias 324 may be formed in accordance with a “via-last” process in which the one or more vias 324 are formed as part of one or more final formation operations of forming the die 240-c-1, or a bonded stack of dies 240 that includes the die 240-c-1. The die 240-c-1 may include multiple contacts 320, and vias 324 may be coupled with at least one of the contacts 320 and with the circuitry of the die 240-c-1. In some examples, contacts 320 may be formed using a single damascene process after a via backside reveal process (e.g., TSV backside reveal process, where the backside of a wafer that includes the die 240-c-1 is trimmed or grinded to the extent that the via is revealed). In some examples, the first operations may include an evaluation whether the die 240-c-1 (e.g., on the wafer) satisfies one or more performance expectations (e.g., based on probing one or more aluminum pads of the die 240-c-1 such as the contacts 322, which may be prior to performing a bonding operation, such that the die 240-c-1 may be a known good die). In some examples, at least for the first operations, one or more aluminum pads that are used for probing may have an associated passivation layer removed, while other remaining aluminum pads may remain with a thin layer of passivation.

The first operations may also include bonding (e.g., via a front-to-front fusion bond) the semiconductor component (e.g., wafer) that includes die 240-c-1 to a carrier 405 (e.g., a sacrificial carrier, a sacrificial silicon material), which may be based on bonding a side 325 of the die 240-c-1 to a surface of the carrier 405. In some examples, the first operations may include forming one or more contacts 320 in a side 315 of the die 240-c-1. In some examples, the side 315 may be associated with the contacts 320 and with a dielectric material 375. In some examples, the first operations may include a first edge trim of the system 400 (e.g., of a semiconductor component that includes the die 240-c-1) based on the formation of the die 240-c-1 and a second edge trim operation performed on the system 400 (e.g., on a semiconductor component with the die 240-c-1 and the carrier 405) based on bonding a wafer that includes the die 240-c-1 with the carrier 405. An edge trim operation may be associated with removing (e.g., cutting, grinding) one or more edges of a device (e.g., the system 400, along the x-direction, along the y-direction) to mitigate chipping, cracking, and other potentially adverse effects during the fabrication process.

FIG. 4B shows an example of a cross-sectional view of the system 400 after a second set of one or more fabrication operations. For example, the second operations may include forming or providing a semiconductor component (e.g., a wafer) with one or more dies 240-c-2 (e.g., as a second semiconductor component), which may include a respective substrate 305 and respective dielectric materials 310. In the second operations, one or more dies 240-c-2 may be singulated from a semiconductor wafer, or may be included in a semiconductor wafer (e.g., before singulation). The second operations may include forming the contacts 340 at a side 335 of the die 240-c-2. The contacts 340 may be formed using a dual damascene process, which may include formation of contacts 340 that are coupled with contacts 342 through a via. In some examples, the contacts 340 may be formed over the contacts 342 of the die 240-c-2. The contacts 342 may be configured for coupling the contacts 340 with circuitry of the die 240-c-2. The second operations may also include forming one or more vias 344 through the substrate 305 of the die 240-c-2. In some examples, the vias 344 may be formed in accordance with a “via-middle” process in which the one or more vias 344 are formed prior to the formation of one or more other components of the die 240-c-2, or before bonding with other die(s) 240-c. In some other examples, vias 344 may be formed in accordance with a “via-last” process in which the one or more vias 344 are formed as part of one or more final formation operations of forming the die 240-c-2, or after bonding the die 240-c-2 with the die 240-c-1. Vias 344 may be coupled with at least one of contacts 340 and with the circuitry of the die 240-c-2. In some examples, the second operations may include a third edge trim operation (e.g., performed on the die 240-c-2) based on forming the die 240-c-2. The second operations may also include an evaluation whether the die 240-c-2 (e.g., on the wafer), or a combination of the dies 240-c-2 and 240-c-1, satisfies one or more performance expectations (e.g., based on probing one or more aluminum pads of the die 240-c-2 such as the contacts 342, which may be prior to performing a bonding operation). In some examples, at least for the second operations, one or more aluminum pads that are used for probing may have an associated passivation layer removed, while other remaining aluminum pads may remain with a thin layer of passivation.

The second operations may also include bonding the die 240-c-2 to the die 240-c-1 (e.g., as a front-to-back bonding, as a W2W bonding, as a D2D bonding, as a hybrid bonding). In some examples, the bonding may be based on fusing contacts 320 with contacts 340. Additionally, or alternatively, bonding the die 240-c-2 to the die 240-c-1 may be based on fusing the dielectric material 375 with the dielectric material 380. In some examples, the bonded stack of dies 240-c-1 and 240-c-2 may be considered a two-high (2H) F2B arrangement, which may be adapted for (e.g., finished for) bonding with another stack (e.g., another 2H F2B arrangement, without bonding a third or further die 240-c, such as die 240-c-3, omitting the third and fourth sets of operations)

FIG. 4C shows an example of a cross-sectional view of the system 400 after a third set of one or more fabrication operations. For example, the third operations may include forming the contacts 350 of the die 240-c-2 after a backside via reveal process (e.g., TSV backside reveal process, where the backside of the wafer with die 240-c-2 is trimmed or grinded to the extent that the via is revealed). The contacts 350 may be formed on a side 345 of the die 240-c-2 that is opposite the side 335. In some examples, the contacts 350 may be formed using a single damascene process. In some examples, forming the contacts 350 may be based on removing (e.g., cutting, grinding, planarizing) a portion of the substrate 305 of the die 240-c-2 and forming a dielectric material 385 over a surface of the die 240-c-2 (e.g., at the side 345).

FIG. 4D shows an example of a cross-sectional view of the system 400 after a fourth set of one or more fabrication operations. For example, the fourth operations may include forming or providing a semiconductor component (e.g., a wafer) that includes one or more dies 240-c-3 (e.g., as a third semiconductor component), which may include a respective substrate 305 and respective dielectric materials 310. The die 240-c-3 may be singulated from a semiconductor wafer, or may be included in a semiconductor wafer (e.g., before singulation). The fourth operations may include forming the contacts 360 at a side 355 of the die 240-c-3. In some examples, the contacts 360 may be formed using a dual damascene process, which may include formation of contacts 360 that are coupled with contacts 362 through a via. In some examples, contacts 360 may be formed over a set of multiple contacts 362 of the die 240-c-3. The contacts 362 may be configured for coupling the contacts 360 with the circuitry of the die 240-c-3. The fourth operations may also include forming one or more vias 364 through the substrate 305 of the die 240-c-3. In some examples, the vias 364 may be formed in accordance with a “via-middle” process in which the one or more vias 364 are formed prior to the formation of one or more other components of the die 240-c-3, or before bonding with other die(s) 240-c. In some other examples, vias 364 may be formed in accordance with a “via-last” process in which the one or more vias 364 are formed as part of one or more final formation operations of forming the die 240-c-3, or after bonding the die 240-c-3 with the die 240-c-2. The one or more vias 364 may be coupled with the contacts 362 (e.g., by way of the BEOL circuitry of the die 240-c-3) and with the circuitry of the die 240-c-3. In some examples, the contacts 360 and a dielectric material 390 may be associated with a side 355 of the die 240-c-3.

The fourth operations may include bonding the die 240-c-3 to the die 240-c-2 (e.g., as a front-to-back bonding, as a W2W bonding, as a D2D bonding, as a hybrid bonding). In some examples, the bonding may be based on fusing contacts 350 with contacts 360. Additionally, or alternatively, bonding the die 240-c-3 to the die 240-c-2 may be further based on fusing the dielectric material 385 with the dielectric material 390. In some examples, as part of the fourth operations, the system 400 may be inverted along the z-axis (e.g., flipped about the x-axis or the y-axis).

FIG. 4E shows an example of a cross-sectional view of the system 400 after a fifth set of one or more fabrication operations. For example, the fifth operations may include exposing the contacts 322 of the die 240-c-1 based on (e.g., after) separating (e.g., removing) the die 240-c-1 from the carrier 405, or on removing a portion of the dielectric material 310 of the die 240-c-1, or both. In some examples, the contacts 322 may facilitate one or more evaluation operations. For example, fifth operations may include determining, prior to forming contacts (e.g., contacts 330) over the contacts 322, whether the circuitry of the die 240-c-1, the circuitry of the die 240-c-2, the circuitry of the die 240-c-1, or a combination thereof satisfy an evaluation operation (e.g., satisfy a performance expectation), which may be based on probing one or more of the contacts 322 (e.g., such that, after such operations, the system 400 may be a known good system). In some examples, while some if not all of the contacts 322 may have removed passivation (e.g., when exposing the contact 322), a portion of the contacts 342 and 362 for the other dies (die 240-c-2 and die 240-c-3) may not have removed passivation. Although the example of system 400 is illustrated with a stack of three dies 240-c (e.g., in a 3H arrangement), aspects of the techniques of the first through fifth operations may be extended to form a system 400 with a different quantity of dies 240-c, such as a stack or four dies 240-c (e.g., a 4H arrangement), a stack of eight dies 240-c (e.g., an 8H arrangement), a stack of sixteen dies 240-c (e.g., a 16H arrangement), or a stack of twenty four dies 240-c (e.g., a 24H arrangement), among others.

FIG. 4F shows an example of a cross-sectional view of the system 400 after a sixth set of one or more fabrication operations. For example, the sixth operations may include forming contacts 330 over one or more of the contacts 322 based on (e.g., after) exposing the contacts 322. In some examples, at least one contact 322 (e.g., contact 322-a) may not be coupled with circuitry (e.g., of one or more dies 240-c), but a corresponding contact 330 (e.g., contact 330-a) may be formed to facilitate improved bonding strength or uniformity. In some other examples, a contact 330 (e.g., contact 330-a) may be omitted and additional dielectric material 310 may be formed over the corresponding contact 322 (e.g., over contact 322-a). The contacts 322 and the contacts 330 may be associated with a side 325 of the die 240-c-1. In some examples, the sixth operations may include forming the contacts 370 at a side 365 of the die 240-c-3, which may be associated with removing a portion of the dielectric material 310 of the die 240-c-3. In some examples, the formation of contacts 370 may be through a TSV backside reveal process. The one or more vias 364 may be coupled with at least one of the contacts 370.

Accordingly, after the sixth operations, the system 400 may form a semiconductor stack (e.g., in accordance with a 3H F2B arrangement) and may be prepared for integration with other systems 400 and/or other semiconductor components (e.g., logic dies, host dies). For example, one or more additional operations may include coupling the system 400 (e.g., the semiconductor stack) with one or more other semiconductor stacks (e.g., for a stack of two systems 400, four systems 400, or eight systems 400, among other examples, not shown). Such a coupling may be based on the contacts 330 and/or the contacts 370. In some examples, the one or more other semiconductor stacks may respectively include one or more dies 240-c (e.g., two dies 240-c, three dies 240-c, more than three dies 240-c) or other semiconductor components. Additionally, or alternatively, other operations may include coupling the system 400 with a logic component (e.g., a die 205, as a singulated die 205 or a wafer of dies 205, based on the contacts 370 and/or the contacts 330). In some examples, the logic component may include circuitry operable to control one or more operations of the circuitry of the die 240-c-1, the die 240-c-2, the die 240-c-3, or a combination thereof.

Thus, by bonding multiple dies 240-c together (e.g., bonding two or more semiconductor components, such as three semiconductor components, together as a group before solder-based bonding), a system 400 may support a reduced height dimension (e.g., along the z-direction). For example, the system 400 may include a relatively smaller quantity of contacts 330 (e.g., solder bumps), which may reduce overall system height. Accordingly, semiconductor systems, such as memory systems, may be enabled to support a greater storage capacity or greater storage density based on supporting a relatively greater quantity of dies 240-c that may be included in a stacked architecture (e.g., in accordance with a stack of 8 dies 240-c, in accordance with a stack of 16 dies 240-c, in accordance with a stack of 24 dies 240-c) while remaining within a height constraint. Further, bonding the multiple dies 240 based on techniques herein may improve a manufacturing yield of systems 400. Accordingly, by applying one or more techniques herein semiconductor systems may be manufactured with improved yield, increased storage capacity, and improved performance, among other benefits.

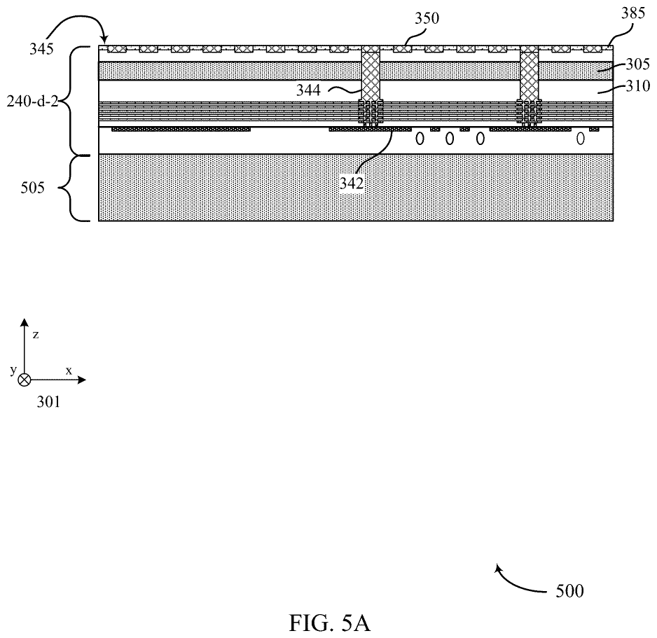

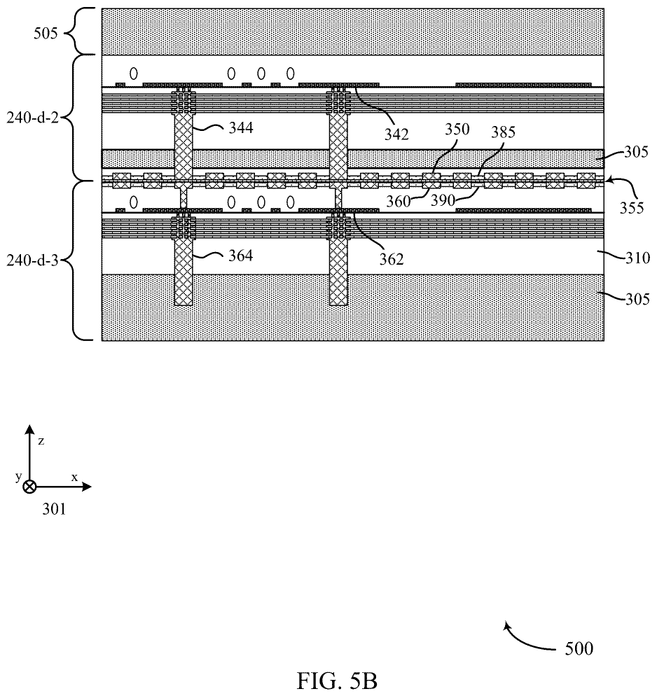

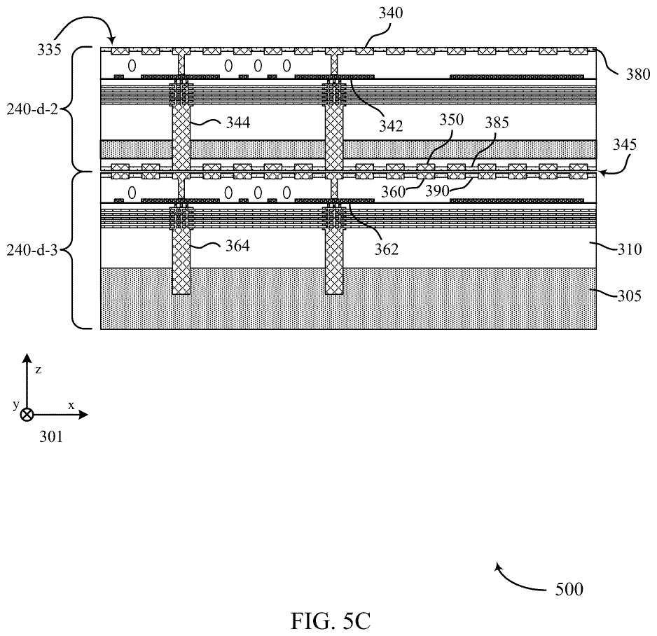

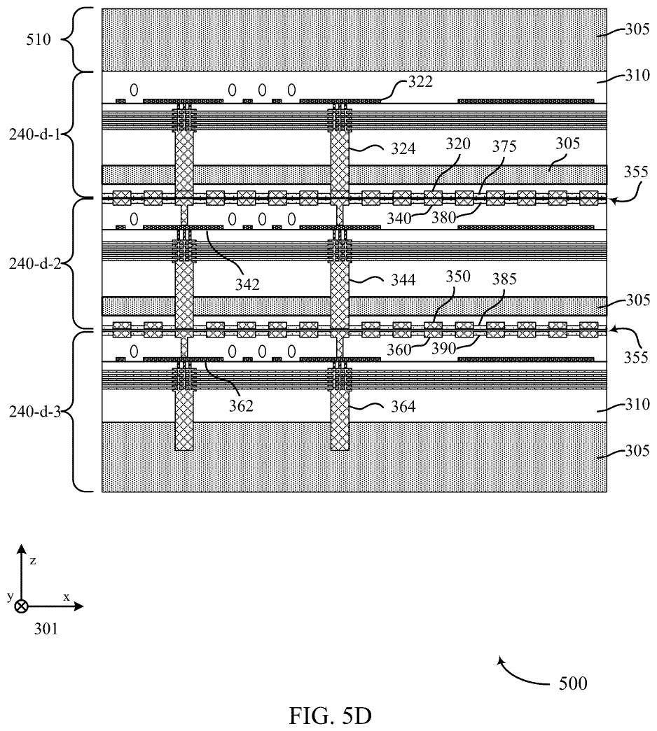

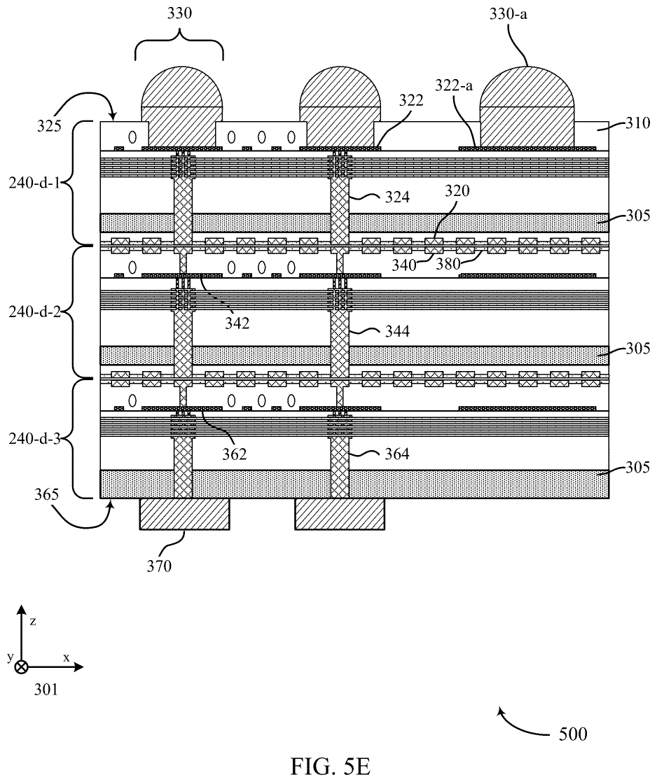

FIGS. 5A through 5E illustrate examples of operations that support bonded semiconductor groups in stacked memory architectures in accordance with examples as disclosed herein. Operations described with reference to FIGS. 5A through 5E may be performed in addition, or in alternative to the operations described with reference to FIGS. 4A through 4F. That is, one or more or more operations described as being performed with reference to FIGS. 4A through 4F may be performed (e.g., added) in any combination with the operations of FIGS. 5A through 5E, and vice-versa.

Operations are illustrated with reference to a system 500 (e.g., a semiconductor system, a semiconductor stack, a semiconductor device, a semiconductor subcomponent), which may be an example of or include an electronic device (e.g., a semiconductor system 300, a system 100, a memory system 110, a host system 105, a system 200). For example, FIGS. 5A through 5E may illustrate aspects of a second sequence of operations that support manufacturing a system 100 or a portion thereof, a system 200 or a portion thereof, a semiconductor system 300 or a portion thereof, or some other device. Each of the figures may be described with reference to an x-direction, a y-direction, and a z-direction of a coordinate system 301. Operations illustrated in and described with reference to FIGS. 5A through 5E may be performed by a manufacturing system, such as a semiconductor fabrication system configured to perform additive operations (e.g., deposition, epitaxy, bonding), subtractive operations (e.g., etching, trenching, planarizing, polishing, grinding, scraping), modifying operations (e.g., oxidizing, doping, reacting, converting), and supporting operations (e.g., masking, patterning, photolithography, aligning), among other operations that support the described techniques.

In some examples, portions of the system 500 that are illustrated with a same fill pattern may be formed of same or similar materials and portions that are illustrated with different patterns may be formed of different materials. Various dielectric materials are described herein, which may include an aluminum nitride, a silicon carbide, a silicon oxide, a silicon nitride, a silicon carbon nitride, a tetraethyl orthosilicate (TEOS), a boron arsenide, some other dielectric material, or any combination thereof. Additionally, conductive materials described herein may include copper, aluminum, tungsten, titanium, some other conductive material, or any combination thereof.

FIG. 5A shows an example of a cross-sectional view of the system 500 after a first set of one or more fabrication operations. For example, the first operations may include bonding a die 240-d-2 (e.g., a second semiconductor component) to a carrier 505 (e.g., to a sacrificial carrier silicon material, via a fusion bond). The die 240-d-2 may be formed in accordance with one or more techniques described herein for forming other dies 240 (e.g., including techniques for forming dies 240-c with reference to FIGS. 4A through 4F). For example, the die 240-d-2 may be formed to include a substrate 305, dielectric materials 310, circuitry (e.g., second memory array circuitry, BEOL circuitry), vias 344, contacts 350, contacts 342, and dielectric material 385. In some examples, the contacts 350 and the dielectric material 385 may be included in a side 345 of the die 340-d-2. In some examples, the first operations may include a first edge trim of the system 500 (e.g., on the die 240-d-2) based on forming the die 240-d-2 and a second edge trim operation performed on the system 500 (e.g., on the die 240-c-1 and the carrier 505) based on bonding the die 240-d-2 to the carrier 505.

FIG. 5B shows an example of a cross-sectional view of the system 500 after a second set of one or more fabrication operations. For example, the second operations may include bonding a die 240-d-3 (e.g., a third semiconductor component) to the die 240-d-2 (e.g., as a front-to-back bonding, as a W2W bonding, as a D2D bonding, as a hybrid bonding). The die 240-d-3 may be formed in accordance with one or more techniques described herein for forming other dies 240 (e.g., including techniques for forming dies 240-c with reference to FIGS. 4A through 4F). For example, the die 240-c-3 may be formed to include a respective substrate 305, dielectric materials 310, circuitry (e.g., third memory array circuitry, BEOL circuitry), vias 364, contacts 360, contacts 362, and a dielectric material 390. In some examples, the contacts 360 and the dielectric material 390 may be included in a side 355 of the die 240-d-3. In some examples, bonding the die 240-d-3 with the die 240-d-2 may be based on a fusion of contacts 350 with contacts 360 and on a fusion of the dielectric material 385 with the dielectric material 390. In some examples, as part of the second operations, the system 500 may be inverted along the z-axis (e.g., flipped about the x-axis or the y-axis).

FIG. 5C shows an example of a cross-sectional view of the system 500 after a third set of one or more fabrication operations. For example, the third operations may include separating the die 240-d-2 from the carrier 505 (e.g., based on grinding, cutting, thinning, planarizing, or otherwise removing the carrier 505). The third operations may also include forming contacts 340 at a side 335 of the die 340-d-2. The contacts 340 may be formed over the contacts 342. The third operations may also include forming the dielectric material 380 at the side 335 of the die 340-d-2.

FIG. 5D shows an example of a cross-sectional view of the system 500 after a fourth set of one or more fabrication operations. For example, the fourth operations may include bonding a die 240-d-1 (e.g., a first semiconductor component) to the die 240-d-2 based on forming the contacts 340. The die 240-d-1 may be formed in accordance with one or more techniques described herein for forming other dies 240 (e.g., including techniques for forming die 240-c with reference to FIGS. 4A through 4F). For example, the die 240-d-1 may be formed to include a respective substrate 305, dielectric materials 310, circuitry (e.g., first memory array circuitry, BEOL circuitry), vias 324, contacts 320, contacts 322, and a dielectric material 375. In some examples, the contacts 320 and the dielectric material 375 may be included in a side 315 of the die 240-d-1. The die 240-d-1 may be bonded to a carrier 510 (e.g., to a second sacrificial carrier silicon material, via a fusion bond) prior to bonding with the die 240-d-2. In some examples, bonding the die 240-d-1 to the die 240-d-2 may be based on a fusion of the contacts 320 with the contacts 340 and of the dielectric materials 375 with the dielectric materials 380. In some examples, the fourth operations may include a third edge trim of the system 500 (e.g., on the die 240-d-1) based on forming the die 240-d-1 and a fourth edge trim operation performed on the system 500 (e.g., on the die 240-c-1 and the carrier 510) based on bonding the die 240-d-1 to the carrier 510.

FIG. 5E shows an example of a cross-sectional view of the system 500 after a fifth set of one or more fabrication operations. For example, the fifth operations may include exposing (e.g., revealing) the contacts 322 of the die 240-c-1. In some examples, exposing the contacts 322 may be based on separating the die 240-c-1 from the carrier 510, or on removing a portion of the dielectric material 310 of the die 240-d-1, or both.

The fifth operations may also include forming contacts 330 (e.g., solder bumps) over one or more of the contacts 322 based on (e.g., after) exposing the contacts 322. In some examples, at least one contact 322 (e.g., contact 322-a) may not be coupled with circuitry (e.g., of one or more dies 240-d), but a corresponding contact 330 (e.g., contact 330-a) may be formed to facilitate improved bonding strength or uniformity. In some other examples, a contact 330 (e.g., contact 330-a) may be omitted and additional dielectric material 310 may be formed over the corresponding contact 322 (e.g., contact 322-a). In some examples, the fifth operations may include forming contacts 370 at a side 365 of the die 240-d-3, which may be coupled with at least one of the vias 364 (e.g., conductive pillars, opposite the solder bumps). Although the vias 364 are shown in the die 240-d-3 during the second set of operations (e.g., in accordance with a “via middle” formation), in some other examples, the vias 364 may be formed during the fifth operations, in accordance with a “via last” formation (e.g., after bonding the die 240-d-3 with the die 240-d-2, such as during the fifth operations or other operations). Although the example of system 500 is illustrated with a stack of three dies 240-d (e.g., in a 3H arrangement), aspects of the techniques of the first through fifth operations may be extended to form a system 500 with a different quantity of dies 240-d, such as a stack or four dies 240-d (e.g., a 4H arrangement), a stack of eight dies 240-d (e.g., an 8H arrangement), a stack of sixteen dies 240-d (e.g., a 16H arrangement), or a stack of twenty four dies 240-d (e.g., a 24H arrangement), among others.

Thus, by bonding multiple dies 240-d together (e.g., in accordance with a 3H F2B arrangement, as shown, or other arrangement), a system 500 may support a reduced height dimension (e.g., along the z-direction). Additionally, manufacture of a system 500 may relatively more reliable based on the use of the carrier 505 and the carrier 510 (e.g., as opposed to using a single carrier). Moreover, the described techniques may support formation of relatively fewer contacts 330 (e.g., solder bumps), which may reduce a height dimension of a system. Accordingly, semiconductor systems, such as memory systems, may be enabled to support a greater storage capacity, a greater storage density, or both based on supporting a relatively greater quantity of dies 240-d that may be included in a stacked architecture (e.g., in accordance with a stack of 8 dies 240-d, in accordance with a stack of 16 dies 240-d, in accordance with a stack of 24 dies 240-d) while remaining within a height constraint. Further, bonding the multiple dies 240 based on techniques herein may improve a manufacturing yield of systems 500. Accordingly, by applying one or more techniques herein semiconductor systems may be manufactured with improved yield, increased storage capacity, and improved performance, among other benefits.

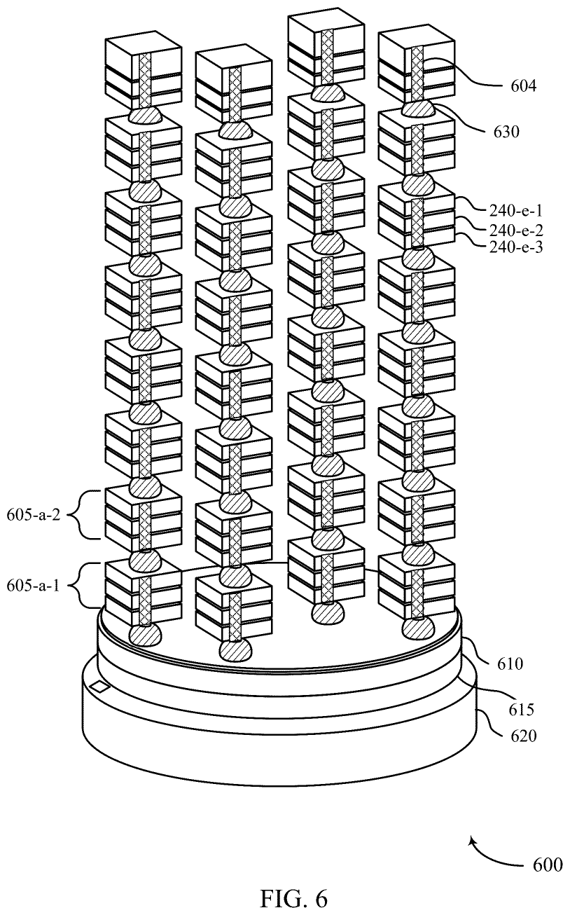

FIG. 6 shows an example of a semiconductor system 600 that supports bonded semiconductor groups in stacked memory architectures in accordance with examples as disclosed herein. A semiconductor system 600 may include multiple semiconductor stacks 605, which may be examples of systems and devices herein such as a semiconductor system 300, a system 400, or a system 500. For example, each stack 605 may include a set of one or more dies 240 (e.g., one die 240 in a 1H arrangement, two dies 240, three dies 240, four dies 240, eight dies 240, sixteen dies 240, twenty four dies 240). Although example quantities of stacks 605 (e.g., eight stacks and twenty-four memory dies, as an 8×3-high front-to-back structure) and example quantities of columns (e.g., four) of stacks 605 are shown, a semiconductor system 600 may include any quantity of stacks 605 and any quantity of columns of stacks, including more or fewer than shown. For example, techniques herein may be applied to support a structure that includes one or more columns of 16 dies 240 or 24 dies 240, and the dies 240 may be fusion-bonded in groups of one (e.g., in a 16×1H arrangement, in a 24×1H arrangement), two (e.g., in an 8×2H arrangement, in a 12×2H arrangement), three (e.g., in an 8×3H arrangement), sixteen (e.g., in a 1×16H arrangement), twenty four (e.g., in a 1×24H arrangement), among other quantities (e.g., in accordance with these and other F2B arrangements).

A semiconductor system 600 may include a first semiconductor stack 605-a-1, which may be associated with first memory array circuitry (e.g., one or more memory arrays 155, memory arrays 250). The stack 605-a-1 may include a first semiconductor die (e.g., a respective die 240-e-1) including a first portion of the first memory array circuitry, a second semiconductor die (e.g., a respective die 240-e-2) including a second portion of the first memory array circuitry, and a third semiconductor die including a third portion of the first memory array circuitry. In accordance with examples described herein, the second semiconductor die may be bonded (e.g., via W2W bonding) with the first semiconductor die based on a fusion of first contacts of the first semiconductor die with second contacts of the second semiconductor die. Additionally, the third semiconductor die may be bonded (e.g., via W2W bonding) with the second semiconductor die based on a fusion of third contacts of the second semiconductor die with fourth contacts of the third semiconductor die. Thus, a conductive path 604 (e.g., formed of various vias, contacts, and interconnection circuitry) may be formed through each stack 605, and may support bonding with other stacks 605 based on the contacts 630 (e.g., contacts 330, solder balls, μ-bumps, a solder connection).

The semiconductor system 600 may also include a semiconductor stack 605-a-2 associated with second memory array circuitry. In some examples, a first side (e.g., a front side) of the stack 605-a-1 may be coupled with the stack 605-a-2 (e.g., a back side of the stack 605-a-2) based on a first contact 630 between the stack 605-a-1 and the stack 605-a-2 (e.g., in accordance with a front to back stack-on-stack (SoS) bonding). The stack 605-a-2 may include a fourth semiconductor die (e.g., a respective die 240-e-1) including a first portion of the second memory array circuitry, a fifth semiconductor die (e.g., a respective die 240-e-2) including a second portion of the second memory array circuitry, and a sixth semiconductor die (e.g., a respective die 240-e-3) including a third portion of the second memory array circuitry. In some examples, the fifth semiconductor die may be bonded (e.g., via W2W bonding) with the fourth semiconductor die based on a fusion of fifth contacts of the fourth semiconductor die with sixth contacts of the fifth semiconductor die. Additionally, the sixth semiconductor die may be bonded (e.g., via W2W bonding) with the fifth semiconductor die based on a fusion of seventh contacts of the fifth semiconductor die with eighth contacts of the sixth semiconductor die. the semiconductor stack

In some examples, the semiconductor system 600 may include a logic wafer 610, which may include multiple dies (e.g., one die, such as a die 205, that corresponds to each column of stacks 605). The respective dies of the logic wafer 610 may include control circuitry that is operable to control one or more operations of the memory array circuitry of their corresponding stacks 605. In some examples, a respective die of the logic wafer 610 may be coupled with a second side (e.g., a back side) of a stack 605 (e.g., stack 605-a-1, in accordance with a stack-on-wafer (SoW) bonding) using a respective contact 630 (e.g., another solder connection) between the stack 605 and the respective die of the logic wafer 610. In some examples, the stacks 605 and the logic wafer 610 may be coupled (e.g., at least temporarily) with a carrier wafer 620 based on an adhesive layer 615.

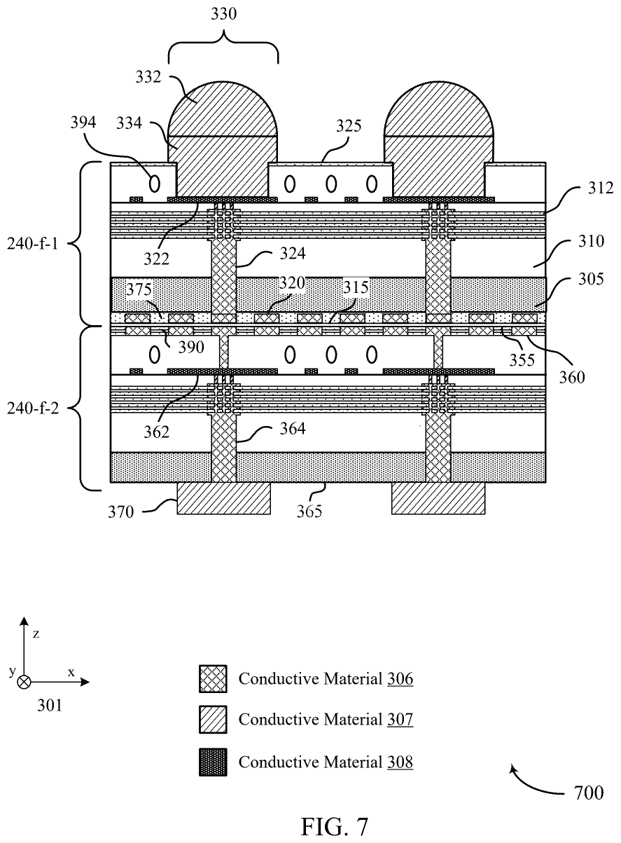

FIG. 7 shows an example of a semiconductor system 700 that supports bonded semiconductor groups in stacked memory architectures in accordance with examples as disclosed herein. The semiconductor system 700 may be an example of or include one or more aspects of a system 100 or a system 200, and may be described with reference to an x-direction, a y-direction, and a z-direction of a coordinate system 301. In some examples, the semiconductor system 700 may be related to the semiconductor system 300 and may illustrate an alternative implementation of the semiconductor grouping. For example, the semiconductor system 700 may illustrate an implementation that includes a stack of components including a die 240-f-1 and a die 240-f-2 (e.g., core dies, DRAM dies, semiconductor components). That is, the semiconductor system 700 may be a non-limiting example of a two-high stack of dies 240-f in which the dies may be bonded in accordance with a front-to-back bonding.

Accordingly, the semiconductor system 700 may include one or more same or similar aspects of the semiconductor system 300 as described with reference to FIG. 3. For example, each die 240-f may include a respective substrate 305 and one or more dielectric materials 310. Each die 240-f may also include respective circuitry (not shown), which may one or more memory arrays 155, memory arrays 250, interface blocks 245, or other circuitry. For example, the die 240-f-1 may include first circuitry and the die 240-f-2 may include second circuitry. In some examples, each circuitry may be included within a portion of a dielectric material 310 and may be at least partially embedded in (e.g., formed at least in part using) the respective substrates 305. Although the techniques are described in the context of dies 240, the techniques may also be applied with other semiconductor components, such as one or more dies 205, or a combination of one or more dies 240 and one or more dies 205, among others.

The dies 240-f may include features formed using various conductive materials including the conductive material 306, the conductive material 307, and the conductive material 308, each of which may be or include copper, aluminum, tungsten, titanium, solder, other metallic conductive material, or a combination thereof (e.g., as a combination of multiple materials, as an alloy, as separate portions of different materials). For example, the conductive material 306 may be or include copper, the conductive material 307 may be or include nickel, aluminum, solder, or a combination thereof, and the conductive material 308 may be or include aluminum, and such different materials may support aspects of differential processing, different bonding techniques, or a combination thereof. The dielectric materials of the dies 240-f may be or include silicon carbide, silicon oxide, silicon nitride, silicon carbon nitride, tetraethyl orthosilicate (TEOS), or a combination thereof. For example, the dielectric materials 310 may include silicon oxide and other dielectric materials of the dies 240-f (e.g., dielectric materials 312) may include silicon carbon nitride.

The die 240-f-1 may have a side 315 (e.g., a back side, a surface) that is associated with (e.g., include, intersect with, be coincident with) a set of contacts 320 (e.g., hybrid bond pads), which may be formed of a conductive material 306 (e.g., copper). The die 240-f-1 may also have a side 325 (e.g., a front side, a surface, opposite the side 315) that is associated with a set of contacts 330 (e.g., solder bumps, μ-bumps, pillars), and the side 325 also may be considered as a side of the semiconductor system 700. The contacts 330 may be formed of a conductive material 307 (e.g., nickel, solder, copper), which may be different than the conductive material 306. For example, the contacts 330 may include portions 332 (e.g., a first subset of contacts) that are configured to support a coupling between the semiconductor system 700 and one or more other semiconductor components (not shown). The contacts 330 may also include portions 334 (e.g., a second subset of contacts) that are configured to support a coupling between the circuitry of the die 240-f-1 and the portions 332. In some examples, the portions 332 and the portions 334 may be formed of respective conductive materials 307 that are different from one another (e.g., the portions 332 may be solder and the portions 334 may be nickel).

The die 240-f-2 may have a side 355 (e.g., a front side) that is associated with a set of contacts 360 (e.g., hybrid bond pads), which may be formed of the conductive material 306. The die 240-f-2 may also have a side 365 (e.g., a back side, opposite the side 355) that is associated with a set of contacts 370 (e.g., nickel pads, backside bumps). In some examples, the side 365 also may be considered as a side of the semiconductor system 700. For example, the semiconductor system 700 may have the contacts 330 (e.g., conductive pillars) on a first side (e.g., the side 325) of the semiconductor system 700 and may have the contacts 370 (e.g., bask side bumps) on a second side (e.g., the side 365) of the semiconductor system 700. The contacts 370 may be formed of the conductive material 307, which may be different than the conductive material 306. In some examples, the side 355 of the die 240-f-2 may be bonded with the side 315 of the die 240-f-1 based on a fusion of contacts 360 with contacts 350.

In some examples, a bond between dies 240-f (e.g., in a system 700) may be associated with a hybrid bonding in which both conductive materials and dielectric materials of the surfaces (e.g., bonding surfaces) each die 240-f are respectively fused together. For example, the side 315 of the die 240-f-1 may be bonded with the side 355 of the die 240-f-2 based also on a fusion of a dielectric material 375 of the die 240-f-1 with a dielectric material 390 of the die 240-f-2.

The die 240-f-1 may also include a set of contacts 322 (e.g., aluminum pads, embedded contacts, intermediate contacts), which may be formed of a conductive material 308 that is different than the conductive material 306, or the conductive material 307, or both. In some examples, one or more of the contacts 322 may facilitate a coupling between the circuitry of the die 240-f-1 and the contacts 330. The die 240-f-2 may also include a set of contacts 362 (e.g., aluminum pads, embedded contacts, intermediate contacts) that are formed of the conductive material 308. In some examples, the contacts 360 may be coupled with the circuitry of the die 240-f-2 based on the contacts 362.

In some examples, dies 240-f may include various vias that support an interconnection of circuitry across the dies 240-f. For example, a semiconductor system 700 may include one or more vias 324 (e.g., TSVs formed of copper) through a substrate 305 of the die 240-f-1, and vias 324 may be coupled one or more of the contacts 320, with one or more of the contacts 330 (e.g., by way of BEOL circuitry and the contacts 322), or both. The semiconductor system 700 may also include one or more vias 364 (e.g., TSVs formed of copper) through a substrate 305 of the die 240-f-2, and vias 364 may be coupled with one or more the contacts 360 (e.g., by way of BEOL circuitry and the contacts 322), with one or more of the contacts 370, or both.

In some examples, circuitry of the die 240-f-1 and circuitry of the die 240-f-2 may include respective portions of memory array circuitry associated with a semiconductor system 700. In some examples, a semiconductor system 700 may be separated (e.g., diced, singulated) from one or more wafers (e.g., the dies 240-f may be bonded together based on a W2W hybrid bond) that includes multiple semiconductor systems 700. In some other examples, the dies 240-f may be bonded after singulation (e.g., in accordance with D2D bonding techniques). In some examples, dies 240-f may include one or more airgaps 394 (e.g., AI airgaps, in dielectric materials 310), which may support improved electrical characteristics and performance of the dies 240-f. Dies 240-f of a semiconductor system 700 may be associated with respective height dimensions (e.g., thickness, along the z-direction), which may be different from or the same as each other. For example, the die 240-f-1 and the die 240-f-2 may be associated with a first height, or the die 240-f-1 may be associated with the first height and the die 240-f-2 may be associated with a second height that is different than (e.g., greater than, less than) the first height, among other examples.

In some examples, aspects of the semiconductor system 700 may be applied to form a structure of stacked dies similar to the semiconductor system 600 as described with reference to FIG. 6. For example, a stack 605 may include two dies 240-e in accordance with one or more aspects of the semiconductor system 700 (e.g., in accordance with the bonding between the die 240-f-1 and the die 240-f-2). In some examples, such techniques may support various structure implementations, including a structure formed of eight (or more) semiconductor systems 700 that are bonded together (e.g., via solder bonding, forming an 8×2-high stack of dies 240).

By including a set of dies 240-f in a bonded stack (e.g., in accordance with a fusion bonding), a semiconductor system 700 may support a reduced thickness (e.g., along the z-direction, compared with solder bonding). For example, a bonded stack of dies 240-f may support a reduced quantity of contacts 330 included a system (e.g., a system 100, a memory system 110, a memory device 145, a system 200), thus supporting a greater quantity of dies 240-f that may be included in the system while satisfying a height constraint. Accordingly, by incorporating one or more aspects of a semiconductor system 700, systems may support increased storage capacity, increased storage density, and improved performance, among other benefits.

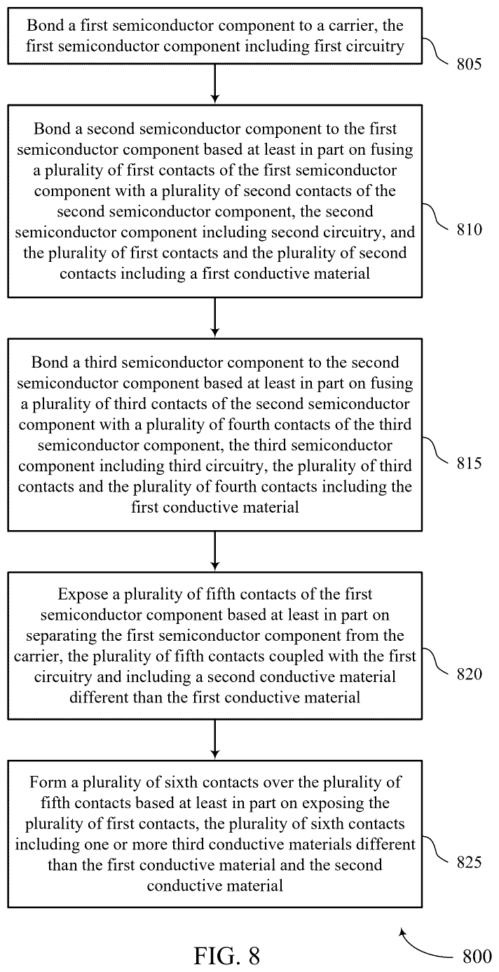

FIG. 8 shows a flowchart illustrating a method or methods 800 that supports bonded semiconductor groups in stacked memory architectures in accordance with examples as disclosed herein. The operations of method 800 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 805, the method may include bonding a first semiconductor component to a carrier, the first semiconductor component including first circuitry.

At 810, the method may include bonding a second semiconductor component to the first semiconductor component based at least in part on fusing a plurality of first contacts of the first semiconductor component with a plurality of second contacts of the second semiconductor component, the second semiconductor component including second circuitry, and the plurality of first contacts and the plurality of second contacts including a first conductive material.

At 815, the method may include bonding a third semiconductor component to the second semiconductor component based at least in part on fusing a plurality of third contacts of the second semiconductor component with a plurality of fourth contacts of the third semiconductor component, the third semiconductor component including third circuitry, the plurality of third contacts and the plurality of fourth contacts including the first conductive material.

At 820, the method may include exposing a plurality of fifth contacts of the first semiconductor component based at least in part on separating the first semiconductor component from the carrier, the plurality of fifth contacts coupled with the first circuitry and including a second conductive material different than the first conductive material.

At 825, the method may include forming a plurality of sixth contacts over the plurality of fifth contacts based at least in part on exposing the plurality of fifth contacts, the plurality of sixth contacts including one or more third conductive materials different than the first conductive material and the second conductive material.

In some examples, an apparatus (e.g., a manufacturing system) as described herein may perform a method or methods, such as the method 800. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for bonding a first semiconductor component to a carrier, the first semiconductor component including first circuitry; bonding a second semiconductor component to the first semiconductor component based at least in part on fusing a plurality of first contacts of the first semiconductor component with a plurality of second contacts of the second semiconductor component, the second semiconductor component including second circuitry, and the plurality of first contacts and the plurality of second contacts including a first conductive material; bonding a third semiconductor component to the second semiconductor component based at least in part on fusing a plurality of third contacts of the second semiconductor component with a plurality of fourth contacts of the third semiconductor component, the third semiconductor component including third circuitry, the plurality of third contacts and the plurality of fourth contacts including the first conductive material; exposing a plurality of fifth contacts of the first semiconductor component based at least in part on separating the first semiconductor component from the carrier, the plurality of fifth contacts coupled with the first circuitry and including a second conductive material different than the first conductive material; and forming a plurality of sixth contacts over the plurality of fifth contacts based at least in part on exposing the plurality of fifth contacts, the plurality of sixth contacts including one or more third conductive materials different than the first conductive material and the second conductive material.

Aspect 2: The method or apparatus of aspect 1, where bonding the second semiconductor component to the first semiconductor component is further based at least in part on fusing a first dielectric material of the first semiconductor component with a second dielectric material of the second semiconductor component, and bonding the third semiconductor component to the second semiconductor component is further based at least in part on fusing a third dielectric material of the second semiconductor component with a fourth dielectric material of the third semiconductor component.

Aspect 3: The method or apparatus of any of aspects 1 through 2, further including operations, features, circuitry, logic, means, or instructions, or any combination thereof for forming, prior to bonding the first semiconductor component with the second semiconductor component, the plurality of second contacts over a plurality of seventh contacts of the second semiconductor component, the plurality of seventh contacts including the second conductive material and configured for coupling the plurality of second contacts with the second circuitry and forming, prior to bonding the third semiconductor component with the second semiconductor component, the plurality of fourth contacts over a plurality of eighth contacts of the third semiconductor component, the plurality of eighth contacts including the second conductive material and configured for coupling the plurality of fourth contacts with the third circuitry.

Aspect 4: The method or apparatus of any of aspects 1 through 3, further including operations, features, circuitry, logic, means, or instructions, or any combination thereof for forming one or more first vias through a substrate of the first semiconductor component, the one or more first vias coupled with at least one of the plurality of first contacts and with the first circuitry; forming one or more second vias through a substrate of the second semiconductor component, the one or more second vias coupled with at least one of the plurality of third contacts and with the second circuitry; and forming one or more third vias through a substrate of the third semiconductor component, the one or more third vias coupled with the third circuitry.

Aspect 5: The method or apparatus of aspect 4, further including operations, features, circuitry, logic, means, or instructions, or any combination thereof for forming a plurality of ninth contacts, where the one or more third vias are coupled with at least one of the plurality of ninth contacts, the plurality of ninth contacts including a fourth conductive material different than the first conductive material.

Aspect 6: The method or apparatus of any of aspects 1 through 5, further including operations, features, circuitry, logic, means, or instructions, or any combination thereof for determining, prior to forming the plurality of sixth contacts, whether the first circuitry, the second circuitry, the third circuitry, or a combination thereof satisfy an evaluation operation based at least in part on probing one or more of the plurality of fifth contacts.

Aspect 7: The method or apparatus of any of aspects 1 through 6, where the first semiconductor component and the method, apparatuses, and non-transitory computer-readable medium further includes operations, features, circuitry, logic, means, or instructions, or any combination thereof for coupling the first semiconductor stack with a second semiconductor stack based at least in part on the plurality of sixth contacts, the second semiconductor stack including a fourth semiconductor component, a fifth semiconductor component, and a sixth semiconductor component.

Aspect 8: The method or apparatus of any of aspects 1 through 7, where the first semiconductor component and the method, apparatuses, and non-transitory computer-readable medium further includes operations, features, circuitry, logic, means, or instructions, or any combination thereof for coupling the first semiconductor stack with a logic component, the logic component including circuitry operable to control one or more operations of the first circuitry, the second circuitry, the third circuitry, or a combination thereof.

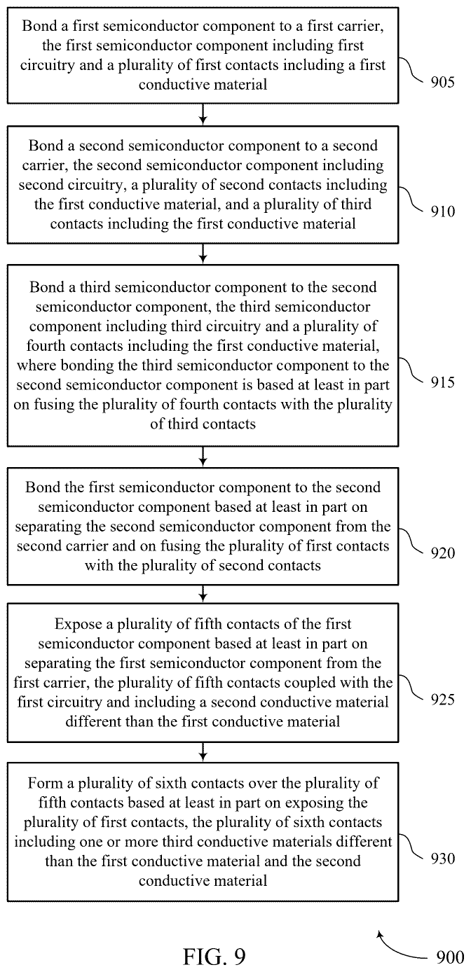

FIG. 9 shows a flowchart illustrating a method or methods 900 that supports bonded semiconductor groups in stacked memory architectures in accordance with examples as disclosed herein. The operations of method 900 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 905, the method may include bonding a first semiconductor component to a first carrier, the first semiconductor component including first circuitry and a plurality of first contacts including a first conductive material.

At 910, the method may include bonding a second semiconductor component to a second carrier, the second semiconductor component including second circuitry, a plurality of second contacts including the first conductive material, and a plurality of third contacts including the first conductive material.

At 915, the method may include bonding a third semiconductor component to the second semiconductor component, the third semiconductor component including third circuitry and a plurality of fourth contacts including the first conductive material, where bonding the third semiconductor component to the second semiconductor component is based at least in part on fusing the plurality of fourth contacts with the plurality of third contacts.

At 920, the method may include bonding the first semiconductor component to the second semiconductor component based at least in part on separating the second semiconductor component from the second carrier and on fusing the plurality of first contacts with the plurality of second contacts.

At 925, the method may include exposing a plurality of fifth contacts of the first semiconductor component based at least in part on separating the first semiconductor component from the first carrier, the plurality of fifth contacts coupled with the first circuitry and including a second conductive material different than the first conductive material.

At 930, the method may include forming a plurality of sixth contacts over the plurality of fifth contacts based at least in part on exposing the plurality of fifth contacts, the plurality of sixth contacts including one or more third conductive materials different than the first conductive material and the second conductive material.

In some examples, an apparatus (e.g., a manufacturing system) as described herein may perform a method or methods, such as the method 900. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 9: A method or apparatus including operations, features, circuitry, logic, means, or instructions, or any combination thereof for bonding a first semiconductor component to a first carrier, the first semiconductor component including first circuitry and a plurality of first contacts including a first conductive material; bonding a second semiconductor component to a second carrier, the second semiconductor component including second circuitry, a plurality of second contacts including the first conductive material, and a plurality of third contacts including the first conductive material; bonding a third semiconductor component to the second semiconductor component, the third semiconductor component including third circuitry and a plurality of fourth contacts including the first conductive material, where bonding the third semiconductor component to the second semiconductor component is based at least in part on fusing the plurality of fourth contacts with the plurality of third contacts; bonding the first semiconductor component to the second semiconductor component based at least in part on separating the second semiconductor component from the second carrier and on fusing the plurality of first contacts with the plurality of second contacts; exposing a plurality of fifth contacts of the first semiconductor component based at least in part on separating the first semiconductor component from the first carrier, the plurality of fifth contacts coupled with the first circuitry and including a second conductive material different than the first conductive material; and forming a plurality of sixth contacts over the plurality of fifth contacts based at least in part on exposing the plurality of fifth contacts, the plurality of sixth contacts including one or more third conductive materials different than the first conductive material and the second conductive material.

Aspect 10: The method or apparatus of aspect 9, where bonding the first semiconductor component to the second semiconductor component is further based at least in part on fusing a first dielectric material of the first semiconductor component with a second dielectric material of the second semiconductor component and bonding the third semiconductor component to the second semiconductor component is further based at least in part on fusing a third dielectric material of the second semiconductor component with a fourth dielectric material of the third semiconductor component.

Aspect 11: The method or apparatus of aspect 10, where the plurality of fifth contacts and the plurality of sixth contacts are associated with a first side of the first semiconductor component; the plurality of first contacts and the first dielectric material are associated with a second side of the first semiconductor component opposite the first side of the first semiconductor component; the plurality of second contacts and the second dielectric material are associated with a first side of the second semiconductor component; the plurality of third contacts and the third dielectric material are associated with a second side of the second semiconductor component opposite the first side of the second semiconductor component; and the plurality of fourth contacts and the fourth dielectric material are associated with a first side of the third semiconductor component.

Aspect 12: The method or apparatus of any of aspects 9 through 11, further including operations, features, circuitry, logic, means, or instructions, or any combination thereof for forming, prior to bonding the third semiconductor component with the second semiconductor component, the plurality of fourth contacts over a plurality of eighth contacts of the third semiconductor component, the plurality of eighth contacts including the second conductive material and configured for coupling the plurality of fourth contacts with the third circuitry and forming, after bonding the third semiconductor component with the second semiconductor component, the plurality of second contacts over a plurality of seventh contacts of the second semiconductor component, the plurality of seventh contacts including the second conductive material and configured for coupling the plurality of second contacts with the second circuitry.

Aspect 13: The method or apparatus of any of aspects 9 through 12, further including operations, features, circuitry, logic, means, or instructions, or any combination thereof for forming one or more first vias through a substrate of the first semiconductor component, the one or more first vias coupled with at least one of the plurality of first contacts and with the first circuitry; forming one or more second vias through a substrate of the second semiconductor component, the one or more second vias coupled with at least one of the plurality of third contacts and with the second circuitry; and forming one or more third vias through a substrate of the third semiconductor component, the one or more third vias coupled with the third circuitry.

Aspect 14: The method or apparatus of aspect 13, further including operations, features, circuitry, logic, means, or instructions, or any combination thereof for forming a plurality of ninth contacts, where the one or more third vias are coupled with at least one of the plurality of ninth contacts, the plurality of ninth contacts including a fourth conductive material different than the first conductive material.

Aspect 15: The method or apparatus of any of aspects 9 through 14, further including operations, features, circuitry, logic, means, or instructions, or any combination thereof for determining, prior to forming the plurality of sixth contacts, whether the first circuitry, the second circuitry, the third circuitry, or a combination thereof satisfy an evaluation operation based at least in part on probing one or more of the plurality of fifth contacts.

Aspect 16: The method or apparatus of any of aspects 9 through 15, where the first semiconductor component and the method, apparatuses, and non-transitory computer-readable medium further includes operations, features, circuitry, logic, means, or instructions, or any combination thereof for coupling the first semiconductor stack with a second semiconductor stack based at least in part on the plurality of sixth contacts, the second semiconductor stack including a fourth semiconductor component, a fifth semiconductor component, and a sixth semiconductor component.

Aspect 17: The method or apparatus of any of aspects 9 through 16, where the first semiconductor component and the method, apparatuses, and non-transitory computer-readable medium further includes operations, features, circuitry, logic, means, or instructions, or any combination thereof for coupling the first semiconductor stack with a fourth semiconductor component, the fourth semiconductor component including circuitry operable to control one or more operations of the first circuitry, the second circuitry, the third circuitry, or a combination thereof.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 18: A semiconductor system, including: a first semiconductor die including first circuitry, the first semiconductor die having a first side including a plurality of first contacts including a first conductive material and having a second side opposite the first side, the second side including a plurality of second contacts including one or more second conductive materials different than the first conductive material; a second semiconductor die including second circuitry, the second semiconductor die having a first side including a plurality of third contacts including the first conductive material and having a second side opposite the first side, the second side including a plurality of fourth contacts including the first conductive material, where the first side of the second semiconductor die is bonded with the first side of the first semiconductor die based at least in part on a fusion of the plurality of first contacts with the plurality of third contacts; and a third semiconductor die including third circuitry, the third semiconductor die having a first side including a plurality of fifth contacts including the first conductive material and having a second side opposite the first side, the second side including a plurality of sixth contacts including a third conductive material different than the first conductive material, where the first side of the third semiconductor die is bonded with the second side of the second semiconductor die based at least in part on a fusion of the plurality of fifth contacts with the plurality of fourth contacts.

Aspect 19: The semiconductor system of aspect 18, where: the first side of the second semiconductor die is bonded with the first side of the first semiconductor die based at least in part on a fusion of a first dielectric material of the first semiconductor die with a second dielectric material of the second semiconductor die; and the first side of the third semiconductor die is bonded with the second side of the second semiconductor die based at least in part on a fusion of a third dielectric material of the third semiconductor die with a fourth dielectric material of the second semiconductor die.

Aspect 20: The semiconductor system of any of aspects 18 through 19, where: the second semiconductor die includes a plurality of seventh contacts including a fourth conductive material different than the first conductive material, where the plurality of third contacts are coupled with the second circuitry based at least in part on the plurality of seventh contacts; and the third semiconductor die includes a plurality of eighth contacts including the fourth conductive material, where the plurality of fifth contacts are coupled with the third circuitry based at least in part on the plurality of eighth contacts.

Aspect 21: The semiconductor system of aspect 20, where: the first conductive material includes copper; the one or more second conductive materials include nickel, aluminum, a solder material, or a combination thereof; the third conductive material includes nickel; and the fourth conductive material includes aluminum.

Aspect 22: The semiconductor system of any of aspects 18 through 21, where the plurality of second contacts includes: a first subset of contacts configured to support a coupling between the semiconductor system and one or more second semiconductor systems; and a second subset of contacts configured to support a coupling between the first circuitry and the first subset of contacts, each contact of the second subset coupled with a respective contact of the first subset of contacts.

Aspect 23: The semiconductor system of aspect 22, where: the one or more second conductive materials include nickel, a solder material, or both for the first subset of contacts; and the one or more second conductive materials include aluminum for the second subset of contacts.

Aspect 24: The semiconductor system of any of aspects 18 through 23, further including: one or more first vias through a substrate of the first semiconductor die, the one or more first vias coupled with at least one of the plurality of first contacts and with at least one of the plurality of second contacts; one or more second vias through a substrate of the second semiconductor die, the one or more second vias coupled with at least one of the plurality of third contacts and with at least one of the plurality of fourth contacts; and one or more third vias through a substrate of the third semiconductor die, the one or more third vias coupled with at least one of the plurality of fifth contacts and with at least one of the plurality of sixth contacts.

Aspect 25: The semiconductor system of any of aspects 18 through 24, where the first circuitry, the second circuitry, and the third circuitry include respective portions of memory array circuitry associated with the semiconductor system.

An apparatus is described. The following provides an overview of aspects of the apparatus as described herein:

Aspect 26: A semiconductor system, including: a first semiconductor stack associated with first memory array circuitry, the first semiconductor stack including: a first semiconductor die including a first portion of the first memory array circuitry; a second semiconductor die including a second portion of the first memory array circuitry, the second semiconductor die bonded with the first semiconductor die based at least in part on a fusion of first contacts of the first semiconductor die with second contacts of the second semiconductor die; and a third semiconductor die including a third portion of the first memory array circuitry, the third semiconductor die bonded with the second semiconductor die based at least in part on a fusion of third contacts of the second semiconductor die with fourth contacts of the third semiconductor die; a second semiconductor stack associated with second memory array circuitry, where a first side of the second semiconductor stack is coupled with the first semiconductor stack based at least in part on a first solder connection between the first semiconductor stack and the second semiconductor stack, the second semiconductor stack including: a fourth semiconductor die including a first portion of the second memory array circuitry; a fifth semiconductor die including a second portion of the second memory array circuitry, the fifth semiconductor die bonded with the fourth semiconductor die based at least in part on a fusion of fifth contacts of the fourth semiconductor die with sixth contacts of the fifth semiconductor die; and a sixth semiconductor die including a third portion of the second memory array circuitry, the sixth semiconductor die bonded with the fifth semiconductor die based at least in part on a fusion of seventh contacts of the fifth semiconductor die with eighth contacts of the sixth semiconductor die; and a seventh semiconductor die including control circuitry operable to control one or more operations of the first memory array circuitry, the second memory array circuitry, or both, where the seventh semiconductor die is coupled with a second side of the second semiconductor stack opposite the first side based at least in part on a second solder connection between the second semiconductor stack and the seventh semiconductor die.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

Some examples and operations described herein may be described with reference to various sides of a respective component. For example, a side of a component may be referred to as a “back side” or “back,” or a “front side” or “front.” A front side of a semiconductor device may refer to a side that includes components such as transistors and capacitors. The front side may also include an electrically conductive metallization structure with chip contact areas. The front side may include front end of line (FEOL), middle of line (MOL), and BEOL layers. The front side may face up during the manufacturing process and may be the primary surface for the device's operation. On the other hand, a back side of a semiconductor device may refer to a side that is opposite to where the main functional elements are located. The back side may be used for various supporting functions that complement the front side. In some examples, the front side may be opposite a substrate material on which the device was formed (e.g., opposite of a back side). In some examples, the back side may be a same side as a substrate material (e.g., a silicon substrate) on which the component was formed (e.g., a substrate for mechanical support during formation).

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A semiconductor system, comprising:
a first semiconductor die comprising first circuitry, the first semiconductor die having a first side comprising a plurality of first contacts comprising a first conductive material and having a second side opposite the first side, the second side comprising a plurality of second contacts comprising one or more second conductive materials different than the first conductive material;
a second semiconductor die comprising second circuitry, the second semiconductor die having a first side comprising a plurality of third contacts comprising the first conductive material and having a second side opposite the first side, the second side comprising a plurality of fourth contacts comprising the first conductive material, wherein the first side of the second semiconductor die is bonded with the first side of the first semiconductor die based at least in part on a fusion of the plurality of first contacts with the plurality of third contacts; and
a third semiconductor die comprising third circuitry, the third semiconductor die having a first side comprising a plurality of fifth contacts comprising the first conductive material and having a second side opposite the first side, the second side comprising a plurality of sixth contacts comprising a third conductive material different than the first conductive material, wherein the first side of the third semiconductor die is bonded with the second side of the second semiconductor die based at least in part on a fusion of the plurality of fifth contacts with the plurality of fourth contacts.

2. The semiconductor system of claim 1, wherein:
the first side of the second semiconductor die is bonded with the first side of the first semiconductor die based at least in part on a fusion of a first dielectric material of the first semiconductor die with a second dielectric material of the second semiconductor die; and
the first side of the third semiconductor die is bonded with the second side of the second semiconductor die based at least in part on a fusion of a third dielectric material of the third semiconductor die with a fourth dielectric material of the second semiconductor die.

3. The semiconductor system of claim 1, wherein:
the second semiconductor die comprises a plurality of seventh contacts comprising a fourth conductive material different than the first conductive material, wherein the plurality of third contacts are coupled with the second circuitry based at least in part on the plurality of seventh contacts; and
the third semiconductor die comprises a plurality of eighth contacts comprising the fourth conductive material, wherein the plurality of fifth contacts are coupled with the third circuitry based at least in part on the plurality of eighth contacts.

4. The semiconductor system of claim 3, wherein:
the first conductive material comprises copper;
the one or more second conductive materials comprise nickel, aluminum, a solder material, or a combination thereof;
the third conductive material comprises nickel; and
the fourth conductive material comprises aluminum.

5. The semiconductor system of claim 1, wherein the plurality of second contacts comprises:
a first subset of contacts configured to support a coupling between the semiconductor system and one or more second semiconductor systems; and
a second subset of contacts configured to support a coupling between the first circuitry and the first subset of contacts, each contact of the second subset of contacts coupled with a respective contact of the first subset of contacts.

6. The semiconductor system of claim 5, wherein:
the one or more second conductive materials comprise nickel, a solder material, or both for the first subset of contacts; and
the one or more second conductive materials comprise aluminum for the second subset of contacts.

7. The semiconductor system of claim 1, further comprising:
one or more first vias through a substrate of the first semiconductor die, the one or more first vias coupled with at least one of the plurality of first contacts and with at least one of the plurality of second contacts;
one or more second vias through a substrate of the second semiconductor die, the one or more second vias coupled with at least one of the plurality of third contacts and with at least one of the plurality of fourth contacts; and
one or more third vias through a substrate of the third semiconductor die, the one or more third vias coupled with at least one of the plurality of fifth contacts and with at least one of the plurality of sixth contacts.

8. The semiconductor system of claim 1, wherein the first circuitry, the second circuitry, and the third circuitry comprise respective portions of memory array circuitry associated with the semiconductor system.

9. A method for manufacturing a semiconductor system, comprising:
bonding a first semiconductor component to a carrier, the first semiconductor component comprising first circuitry;
bonding a second semiconductor component to the first semiconductor component based at least in part on fusing a plurality of first contacts of the first semiconductor component with a plurality of second contacts of the second semiconductor component, the second semiconductor component comprising second circuitry, and the plurality of first contacts and the plurality of second contacts comprising a first conductive material;
bonding a third semiconductor component to the second semiconductor component based at least in part on fusing a plurality of third contacts of the second semiconductor component with a plurality of fourth contacts of the third semiconductor component, the third semiconductor component comprising third circuitry, the plurality of third contacts and the plurality of fourth contacts comprising the first conductive material;
exposing a plurality of fifth contacts of the first semiconductor component based at least in part on separating the first semiconductor component from the carrier, the plurality of fifth contacts coupled with the first circuitry and comprising a second conductive material different than the first conductive material; and
forming a plurality of sixth contacts over the plurality of fifth contacts based at least in part on exposing the plurality of fifth contacts, the plurality of sixth contacts comprising one or more third conductive materials different than the first conductive material and the second conductive material.

10. The method of claim 9, wherein:
bonding the second semiconductor component to the first semiconductor component is further based at least in part on fusing a first dielectric material of the first semiconductor component with a second dielectric material of the second semiconductor component; and
bonding the third semiconductor component to the second semiconductor component is further based at least in part on fusing a third dielectric material of the second semiconductor component with a fourth dielectric material of the third semiconductor component.

11. The method of claim 9, further comprising:
forming, prior to bonding the first semiconductor component with the second semiconductor component, the plurality of second contacts over a plurality of seventh contacts of the second semiconductor component, the plurality of seventh contacts comprising the second conductive material and configured for coupling the plurality of second contacts with the second circuitry; and
forming, prior to bonding the third semiconductor component with the second semiconductor component, the plurality of fourth contacts over a plurality of eighth contacts of the third semiconductor component, the plurality of eighth contacts comprising the second conductive material and configured for coupling the plurality of fourth contacts with the third circuitry.

12. The method of claim 9, further comprising:
forming one or more first vias through a substrate of the first semiconductor component, the one or more first vias coupled with at least one of the plurality of first contacts and with the first circuitry;
forming one or more second vias through a substrate of the second semiconductor component, the one or more second vias coupled with at least one of the plurality of third contacts and with the second circuitry; and
forming one or more third vias through a substrate of the third semiconductor component, the one or more third vias coupled with the third circuitry.

13. The method of claim 12, further comprising:
forming a plurality of ninth contacts, wherein the one or more third vias are coupled with at least one of the plurality of ninth contacts, the plurality of ninth contacts comprising a fourth conductive material different than the first conductive material.

14. The method of claim 9, further comprising:
determining, prior to forming the plurality of sixth contacts, whether the first circuitry, the second circuitry, the third circuitry, or a combination thereof satisfy an evaluation operation based at least in part on probing one or more of the plurality of fifth contacts.

15. The method of claim 9, wherein the first semiconductor component, the second semiconductor component, and the third semiconductor component form a first semiconductor stack, the method further comprising:
coupling the first semiconductor stack with a second semiconductor stack based at least in part on the plurality of sixth contacts, the second semiconductor stack comprising a fourth semiconductor component, a fifth semiconductor component, and a sixth semiconductor component.

16. The method of claim 9, wherein the first semiconductor component, the second semiconductor component, and the third semiconductor component form a first semiconductor stack, the method further comprising:
coupling the first semiconductor stack with a logic component, the logic component comprising circuitry operable to control one or more operations of the first circuitry, the second circuitry, the third circuitry, or a combination thereof.

17. A method for manufacturing a memory system, comprising:
bonding a first semiconductor component to a first carrier, the first semiconductor component comprising first circuitry and a plurality of first contacts comprising a first conductive material;
bonding a second semiconductor component to a second carrier, the second semiconductor component comprising second circuitry, a plurality of second contacts comprising the first conductive material, and a plurality of third contacts comprising the first conductive material;
bonding a third semiconductor component to the second semiconductor component, the third semiconductor component comprising third circuitry and a plurality of fourth contacts comprising the first conductive material, wherein bonding the third semiconductor component to the second semiconductor component is based at least in part on fusing the plurality of fourth contacts with the plurality of third contacts;
bonding the first semiconductor component to the second semiconductor component based at least in part on separating the second semiconductor component from the second carrier and on fusing the plurality of first contacts with the plurality of second contacts;
exposing a plurality of fifth contacts of the first semiconductor component based at least in part on separating the first semiconductor component from the first carrier, the plurality of fifth contacts coupled with the first circuitry and comprising a second conductive material different than the first conductive material; and
forming a plurality of sixth contacts over the plurality of fifth contacts based at least in part on exposing the plurality of fifth contacts, the plurality of sixth contacts comprising one or more third conductive materials different than the first conductive material and the second conductive material.

18. The method of claim 17, wherein:
bonding the first semiconductor component to the second semiconductor component is further based at least in part on fusing a first dielectric material of the first semiconductor component with a second dielectric material of the second semiconductor component; and
bonding the third semiconductor component to the second semiconductor component is further based at least in part on fusing a third dielectric material of the second semiconductor component with a fourth dielectric material of the third semiconductor component.

19. The method of claim 18, wherein:
the plurality of fifth contacts and the plurality of sixth contacts are associated with a first side of the first semiconductor component;
the plurality of first contacts and the first dielectric material are associated with a second side of the first semiconductor component opposite the first side of the first semiconductor component;
the plurality of second contacts and the second dielectric material are associated with a first side of the second semiconductor component;
the plurality of third contacts and the third dielectric material are associated with a second side of the second semiconductor component opposite the first side of the second semiconductor component; and
the plurality of fourth contacts and the fourth dielectric material are associated with a first side of the third semiconductor component.

20. The method of claim 17, further comprising:
forming, prior to bonding the third semiconductor component with the second semiconductor component, the plurality of fourth contacts over a plurality of eighth contacts of the third semiconductor component, the plurality of eighth contacts comprising the second conductive material and configured for coupling the plurality of fourth contacts with the third circuitry; and
forming, after bonding the third semiconductor component with the second semiconductor component, the plurality of second contacts over a plurality of seventh contacts of the second semiconductor component, the plurality of seventh contacts comprising the second conductive material and configured for coupling the plurality of second contacts with the second circuitry.

21. The method of claim 17, further comprising:
forming one or more first vias through a substrate of the first semiconductor component, the one or more first vias coupled with at least one of the plurality of first contacts and with the first circuitry;
forming one or more second vias through a substrate of the second semiconductor component, the one or more second vias coupled with at least one of the plurality of third contacts and with the second circuitry; and
forming one or more third vias through a substrate of the third semiconductor component, the one or more third vias coupled with the third circuitry.

22. The method of claim 21, further comprising:
forming a plurality of ninth contacts, wherein the one or more third vias are coupled with at least one of the plurality of ninth contacts, the plurality of ninth contacts comprising a fourth conductive material different than the first conductive material.

23. The method of claim 17, further comprising:
determining, prior to forming the plurality of sixth contacts, whether the first circuitry, the second circuitry, the third circuitry, or a combination thereof satisfy an evaluation operation based at least in part on probing one or more of the plurality of fifth contacts.

24. The method of claim 17, wherein the first semiconductor component, the second semiconductor component, and the third semiconductor component form a first semiconductor stack, the method further comprising:
coupling the first semiconductor stack with a second semiconductor stack based at least in part on the plurality of sixth contacts, the second semiconductor stack comprising a fourth semiconductor component, a fifth semiconductor component, and a sixth semiconductor component.

25. The method of claim 17, wherein the first semiconductor component, the second semiconductor component, and the third semiconductor component form a first semiconductor stack, the method further comprising:
coupling the first semiconductor stack with a fourth semiconductor component, the fourth semiconductor component comprising circuitry operable to control one or more operations of the first circuitry, the second circuitry, the third circuitry, or a combination thereof.

26. A semiconductor system, comprising:
a first semiconductor stack associated with first memory array circuitry, the first semiconductor stack comprising:
a first semiconductor die comprising a first portion of the first memory array circuitry;
a second semiconductor die comprising a second portion of the first memory array circuitry, the second semiconductor die bonded with the first semiconductor die based at least in part on a fusion of first contacts of the first semiconductor die with second contacts of the second semiconductor die; and
a third semiconductor die comprising a third portion of the first memory array circuitry, the third semiconductor die bonded with the second semiconductor die based at least in part on a fusion of third contacts of the second semiconductor die with fourth contacts of the third semiconductor die;
a second semiconductor stack associated with second memory array circuitry, wherein a first side of the second semiconductor stack is coupled with the first semiconductor stack based at least in part on a first solder connection between the first semiconductor stack and the second semiconductor stack, the second semiconductor stack comprising:
a fourth semiconductor die comprising a first portion of the second memory array circuitry;
a fifth semiconductor die comprising a second portion of the second memory array circuitry, the fifth semiconductor die bonded with the fourth semiconductor die based at least in part on a fusion of fifth contacts of the fourth semiconductor die with sixth contacts of the fifth semiconductor die; and
a sixth semiconductor die comprising a third portion of the second memory array circuitry, the sixth semiconductor die bonded with the fifth semiconductor die based at least in part on a fusion of seventh contacts of the fifth semiconductor die with eighth contacts of the sixth semiconductor die; and
a seventh semiconductor die comprising control circuitry operable to control one or more operations of the first memory array circuitry, the second memory array circuitry, or both, wherein the seventh semiconductor die is coupled with a second side of the second semiconductor stack opposite the first side based at least in part on a second solder connection between the second semiconductor stack and the seventh semiconductor die.

27. A semiconductor system formed by a process comprising:
bonding a first semiconductor component to a first carrier, the first semiconductor component comprising first circuitry and a plurality of first contacts comprising a first conductive material;
bonding a second semiconductor component to a second carrier, the second semiconductor component comprising second circuitry, a plurality of second contacts comprising the first conductive material, and a plurality of third contacts comprising the first conductive material;
bonding a third semiconductor component to the second semiconductor component, the third semiconductor component comprising third circuitry and a plurality of fourth contacts comprising the first conductive material, wherein bonding the third semiconductor component to the second semiconductor component is based at least in part on fusing the plurality of fourth contacts with the plurality of third contacts;
bonding the first semiconductor component to the second semiconductor component based at least in part on separating the second semiconductor component from the second carrier and on fusing the plurality of first contacts with the plurality of second contacts;
exposing a plurality of fifth contacts of the first semiconductor component based at least in part on separating the first semiconductor component from the first carrier, the plurality of fifth contacts coupled with the first circuitry and comprising a second conductive material different than the first conductive material; and
forming a plurality of sixth contacts over the plurality of fifth contacts based at least in part on exposing the plurality of fifth contacts, the plurality of sixth contacts comprising one or more third conductive materials different than the first conductive material and the second conductive material.

28. The semiconductor system of claim 27, wherein:
bonding the second semiconductor component to the first semiconductor component is further based at least in part on fusing a first dielectric material of the first semiconductor component with a second dielectric material of the second semiconductor component; and
bonding the third semiconductor component to the second semiconductor component is further based at least in part on fusing a third dielectric material of the second semiconductor component with a fourth dielectric material of the third semiconductor component.

29. The semiconductor system of claim 28, wherein:
the plurality of fifth contacts and the plurality of sixth contacts are associated with a first side of the first semiconductor component;
the plurality of first contacts and the first dielectric material are associated with a second side of the first semiconductor component opposite the first side of the first semiconductor component;
the plurality of second contacts and the second dielectric material are associated with a first side of the second semiconductor component;
the plurality of third contacts and the third dielectric material are associated with a second side of the second semiconductor component opposite the first side of the second semiconductor component; and
the plurality of fourth contacts and the fourth dielectric material are associated with a first side of the third semiconductor component.
